(19) United States
(12) Patent Application Publication
(10) Pub. No.: US 2025/0366041 A1
(43) Pub. Date: Nov. 27, 2025

(54) Inner Spacers for Gate-All-Around Devices and Manufacturing Methods Thereof

(71) Applicant: Taiwan Semiconductor Manufacturing Company, Ltd., Hsin-Chu (TW)

(72) Inventors: Ya-Ting YANG, Tainan City (TW); Chia-Wei CHANG, Taichung City (TW); De-Fang CHEN, Hsinchu City (TW); Wen-Kai LIN, Hsinchu (TW)

(73) Assignee: Taiwan Semiconductor Manufacturing Company, Ltd., Hsin-Chu (TW)

(21) Appl. No.: 18/906,900

(22) Filed: Oct. 4, 2024

Related U.S. Application Data
(60) Provisional application No. 63/650,983, filed on May 23, 2024.

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 84/013; H10D 84/0135; H10D 84/038; H10D 84/83

(57) ABSTRACT

A method includes forming over a stack that includes channel layers interleaved by sacrificial layers, patterning the stack to form a fin-shaped structure, forming a dummy gate stack across the fin-shaped structure, recessing a source/drain region of the fin-shaped structure, selectively removing the sacrificial layers in the channel region to release the channel layers as channel members, depositing a dummy layer in space between the channel members, selectively and partially recessing the dummy layer to form inner spacer recesses, depositing a first dielectric layer in the inner spacer recesses, etching back the first dielectric layer, depositing a second dielectric layer over the first dielectric layer, etching back the second dielectric layer to form inner spacers in the inner spacer recesses, forming a source/drain feature over the source/drain region, removing the dummy gate stack and the dummy layer, and forming a gate structure to wrap around the channel members.

### PRIORITY DATA

This application claims priority to U.S. Provisional Patent Application No. 63/650,983, filed on May 23, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that wrap around a channel region to provide access to the channel region on four sides. The scaling down of the dimensions of the GAA transistors has increased the complexity of semiconductor manufacturing processes. As the minimum feature sizes are reduced, additional problems arise that should be addressed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5, 6, 7, 8, 9, 10, 11, 12, 13, 14, 15, 16, 20, 21, 22, 23, 24, 25, and 26 illustrate fragmentary cross-sectional views of a work-in-progress (WIP) structure during a fabrication process with respect to the method of FIG. 1, according to one or more aspects of the present disclosure.

FIGS. 17A, 17B, 17C, 17D, 17E, 17F, and 17G illustrate an enlarged cross-sectional view of a region containing an inner spacer during a fabrication process with respect to the method of FIG. 1, according to one or more embodiments of the present disclosure.

FIGS. 18A, 18B, 18C, 18D, and 18E illustrate an enlarged cross-sectional view of a region containing an inner spacer during a fabrication process with respect to the method of FIG. 1, according to one or more embodiments of the present disclosure.

FIGS. 19A, 19B, 19C, 19D, and 19E illustrate an enlarged cross-sectional view of a region containing an inner spacer during a fabrication process with respect to the method of FIG. 1, according to one or more embodiments of the present disclosure.

FIGS. 27A, 27B, 27C, and 27D illustrate an enlarged cross-sectional view of a region containing an inner spacer after a replacement gate process with respect to the method of FIG. 1, according to one or more embodiments of the present disclosure.

FIGS. 28A, 28B, 28C, and 28D illustrate an enlarged cross-sectional view of a region containing an inner spacer after a replacement gate process with respect to the method of FIG. 1, according to one or more embodiments of the present disclosure.

FIG. 29 illustrates a fragmentary cross-sectional view of a work-in-progress (WIP) structure with different source/drain region widths after a replacement gate process with respect to the method of FIG. 1, according to one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and fabrication methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. During the removal of the sacrificial materials, inner spacers function to contain the etching process to define a profile of the gate structure and to separate the epitaxial source/drain features from being contacted by the gate structure. Inner spacers may be formed by first forming inner spacer recesses and subsequently depositing dielectric materials in the inner spacer recesses through a conformal deposition process, such as chemical vapor deposition (CVD), atomic layer deposition (ALD), or the like. During a conformal deposition, dielectric materials enter the inner spacer recesses to form the inner spacers but may create a seam inside the inner spacers and an associated dishing on the outer surface of the inner spacers. When etching selectivity between the inner spacers and the sacrificial materials is less than satisfactory, particularly when there is a seam remained in the inner spacers, the inner spacers may be significantly consumed as etching rate is accelerated in the vicinity of a seam. The etching loss of the inner spacers causes the thickness of the inner spacers to be thinner than expected, leading to poor parasitic capacitance performance. In some cases, a short may also occur between the gate structure and the epitaxial source/drain features. Embodiments of the present disclosure advantageously perform a process during the formation of the inner spacers to reduce or eliminate a seam that could otherwise be formed inside the inner spacers and to reduce or eliminate dishing of the inner spacers. The process may also be referred to as the “de-seaming process.”

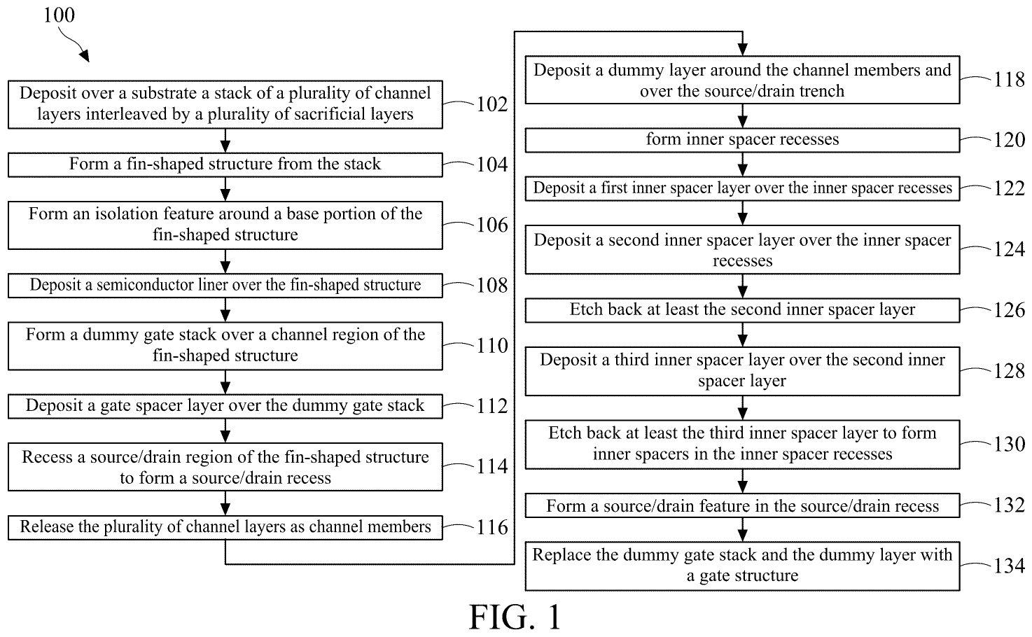

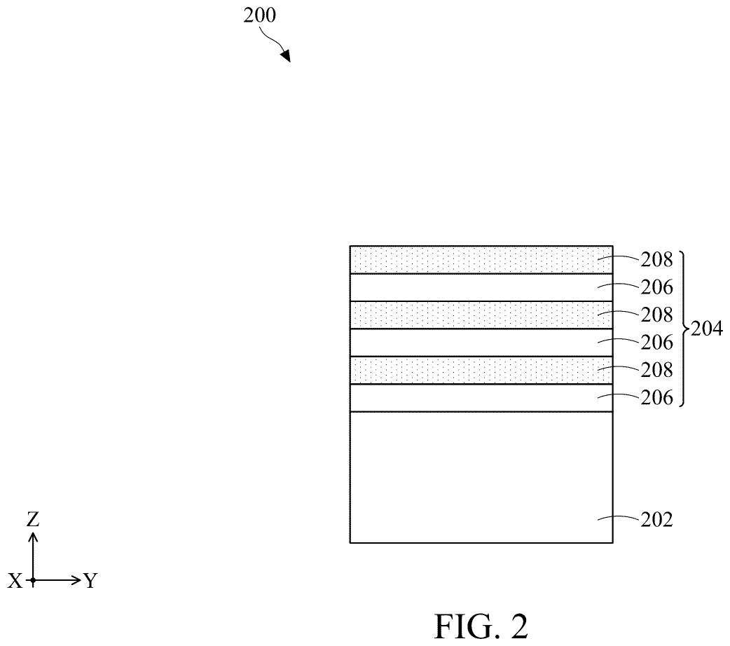

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-29, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 2-29 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

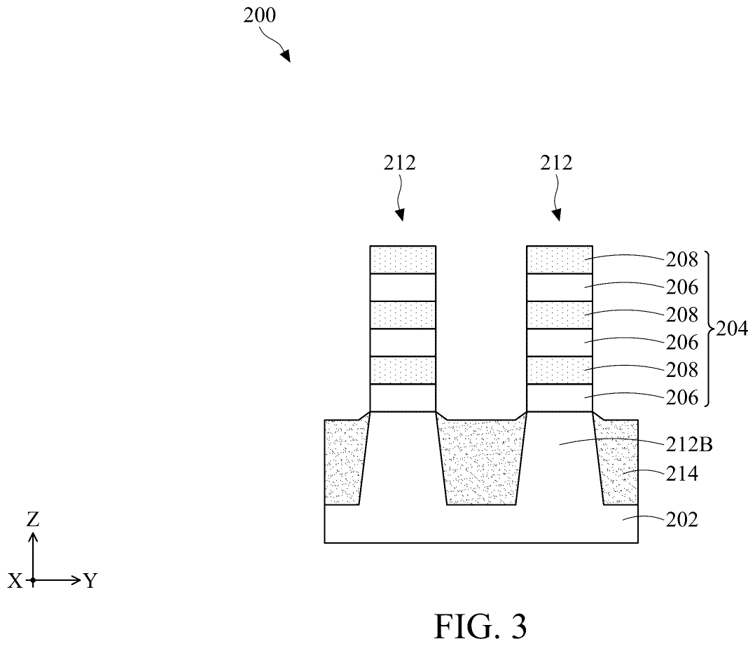

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202 and the patterned stack 204 disposed directly over the base fin structure 212B.

Referring to FIGS. 1 and 3, method 100 includes a block 106 where an isolation feature 214 is formed around a base fin structure 212B of the fin-shaped structures 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

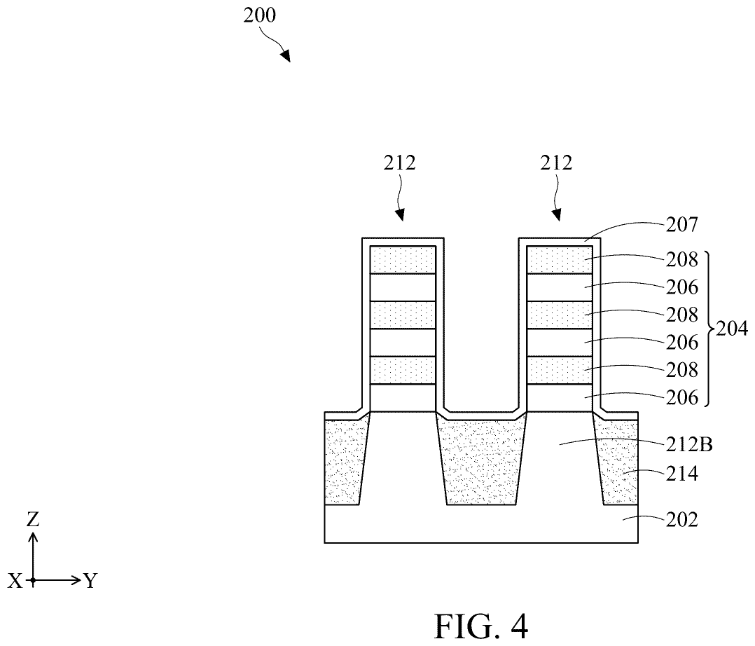

Referring to FIGS. 1 and 4, method 100 includes a block 108 where a semiconductor liner 207 is deposited over the fin-shaped structure 212. After the formation of the isolation feature 214, a semiconductor liner 207 may be deposited over the WIP structure 200, including over the isolation feature 214, over a top surface of the fin-shaped structure 212, and along sidewalls of the fin-shaped structure 212. The semiconductor liner 207 functions to protect the sidewalls of the sacrificial layers 206 as they can sustain undesirable damages during the fabrication processes. In some embodiments, the semiconductor liner 207 may include silicon (Si). In some implementations, the semiconductor liner 207 may be deposited using PVD, CVD, or atomic layer deposition (ALD).

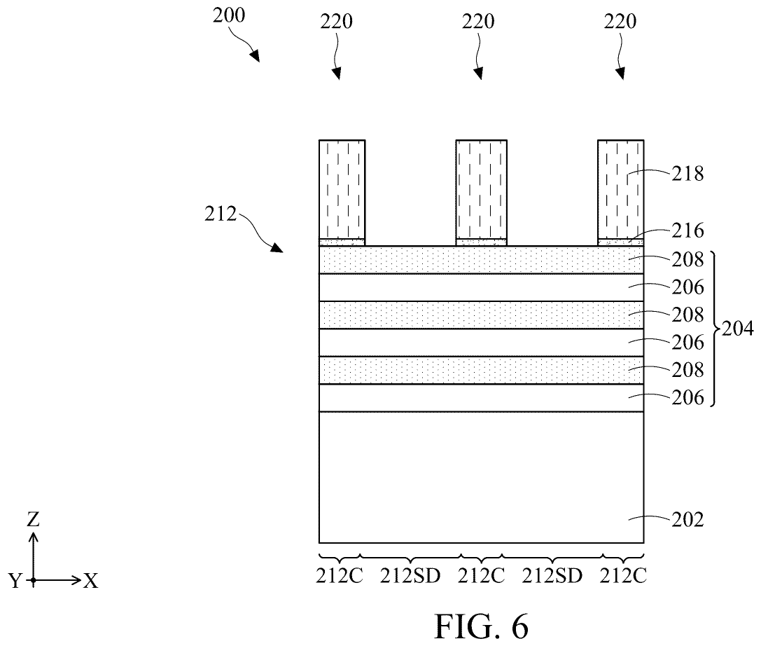

Referring to FIGS. 1, 5 and 6, method 100 includes a block 110 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. In some embodiments illustrated in FIG. 6, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

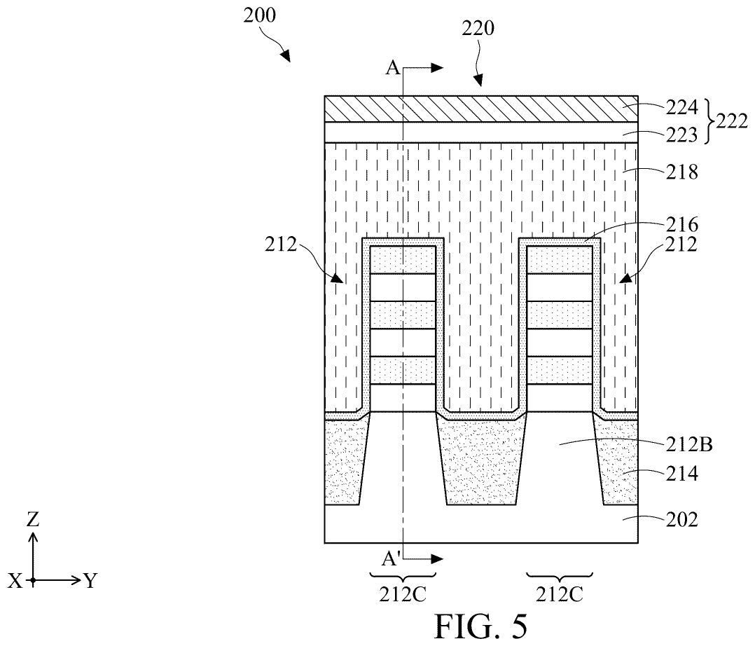

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the WIP structure 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 207 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

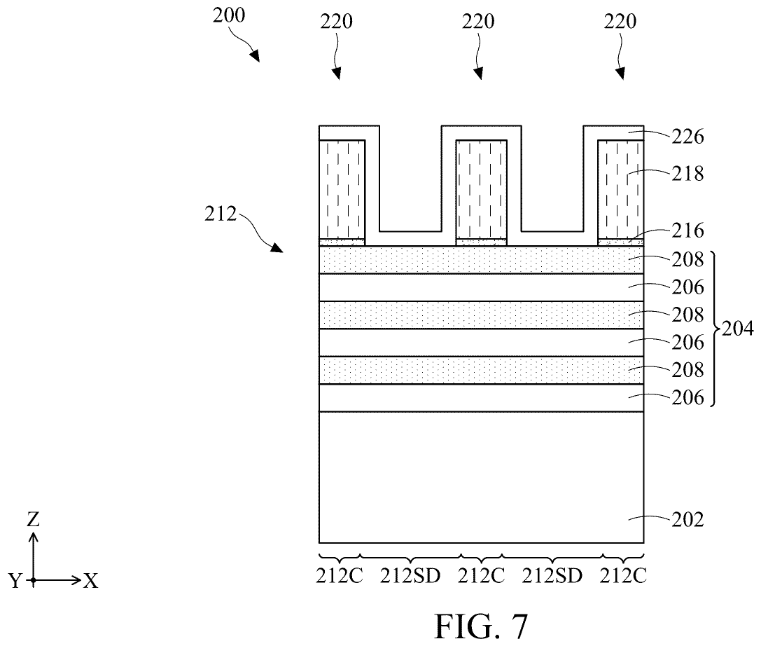

Referring to FIGS. 1 and 7, method 100 includes a block 112 where a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

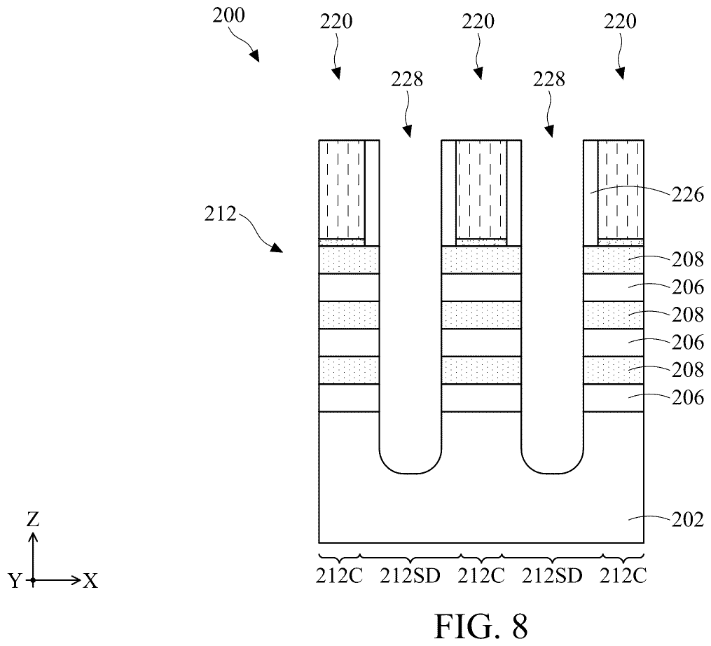

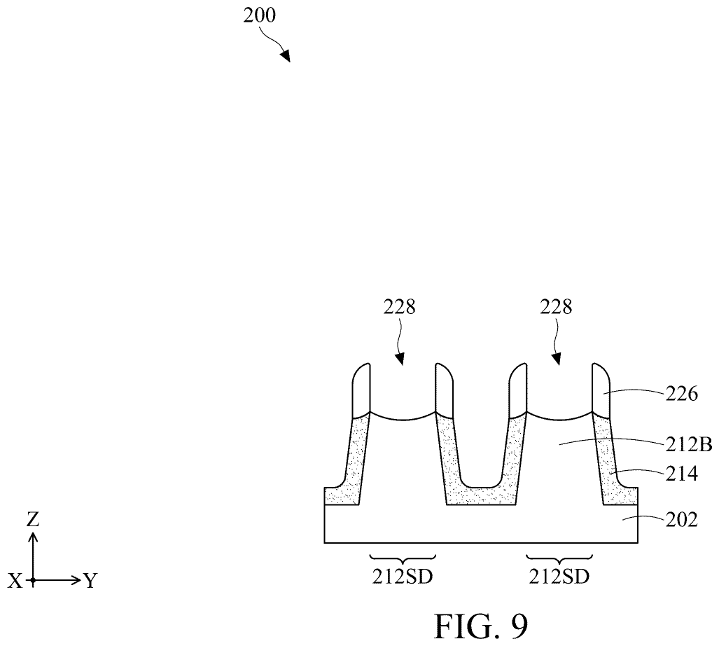

Referring to FIGS. 1, 8 and 9, method 100 includes a block 114 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 9, which includes a fragmentary cross-sectional view across two adjacent source/drain regions 212SD. As shown in FIG. 9, over the source/drain regions 212SD, the majority of the fin-shaped structure 212 is etched away and a top surface of the base fin structure 212B is exposed in the source/drain region 212SD. Because the gate spacer layer 226 etches at a slower rate than the fin-shaped structure 212, the gate spacer layer 226 in the source/drain region 212SD rises above the top surface of the base fin structure 212B.

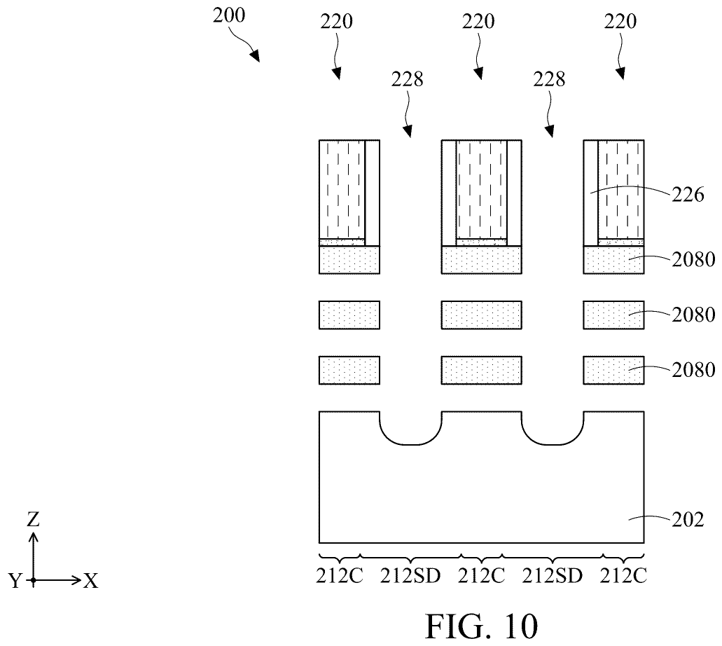

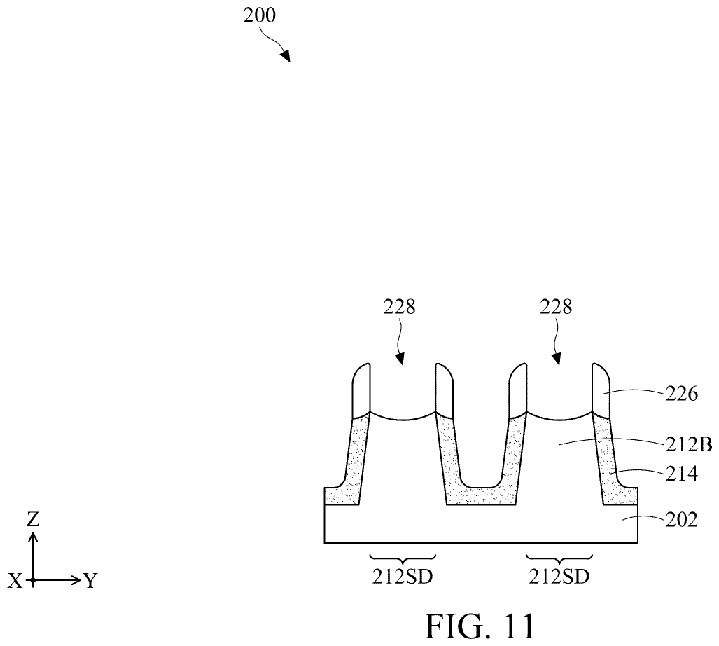

Referring to FIGS. 1, 10 and 11, method 100 includes a block 116 where the plurality of channel layers 208 in the channel regions are released as channel members 2080. Depending on the design, the channel members 2080 may take form of nanowires, nanosheets, or other nanostructures. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 10. The selective removal of the sacrificial layers 206 forms spaces between and around adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Reference is made to FIG. 11, which includes a fragmentary cross-sectional view across two adjacent source/drain regions 212SD. As shown in FIG. 11, at block 116, the base fin structures 212B in the source/drain regions 212SD are not substantially etched.

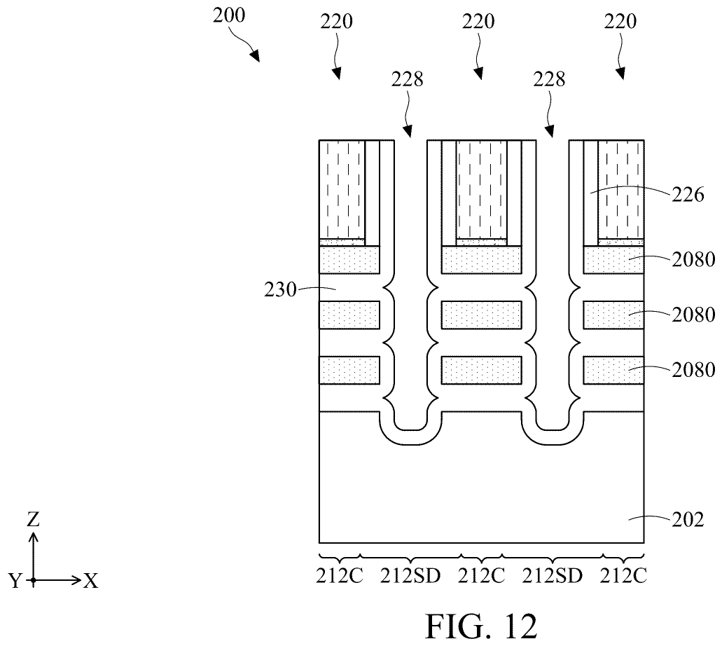

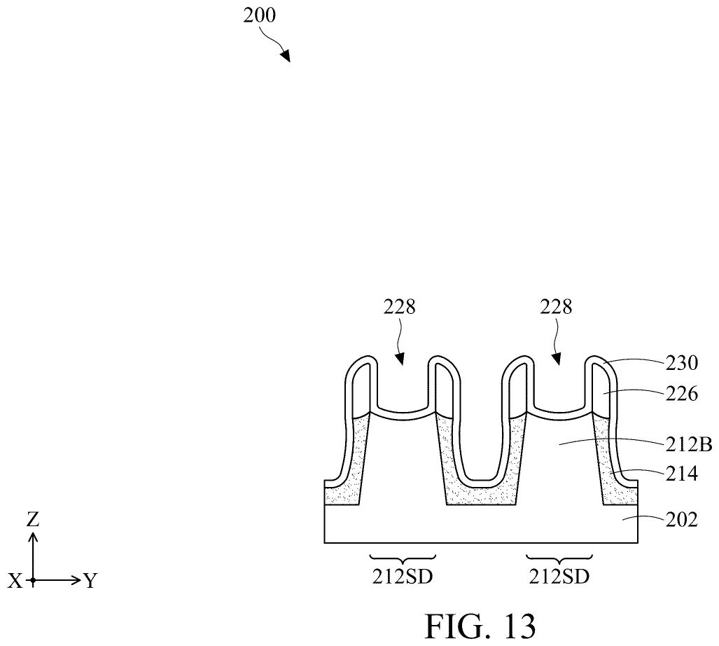

Referring to FIGS. 1, 12 and 13, method 100 includes a block 118 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 12, the dummy layer 230 fills the space among the channel members 2080 and covers end sidewalls of the channel members 2080. Additionally, the dummy layer 230 is in direct contact with a sidewall of the gate spacer layer 226 and a top surface of the substrate 202. Reference is made to FIG. 13, which includes a fragmentary cross-sectional view across two adjacent source/drain regions 212SD. As shown in FIG. 13, the dummy layer 230 extends conformally over the isolation feature 214, sidewalls of the gate spacer layer 226, and top surfaces of the gate spacer layer 226.

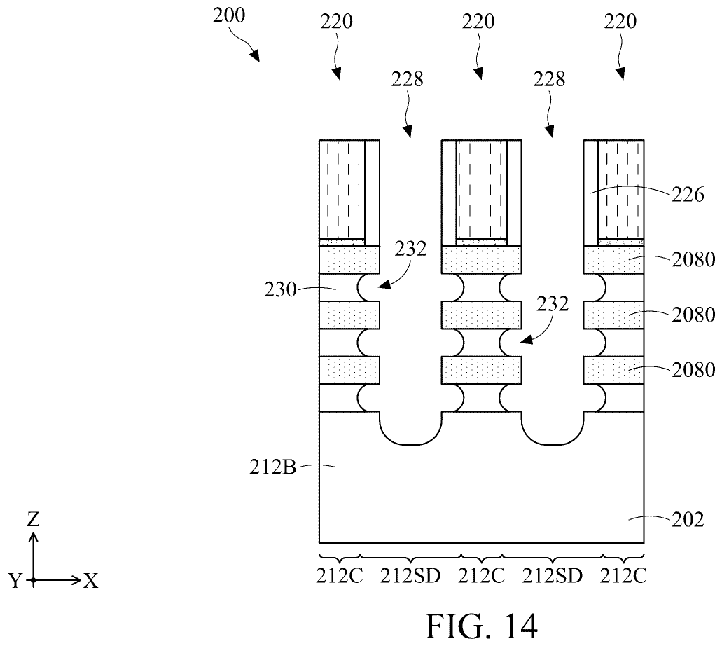

Referring to FIGS. 1 and 14, method 100 includes a block 120 where inner spacer recesses 232 are formed. The dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

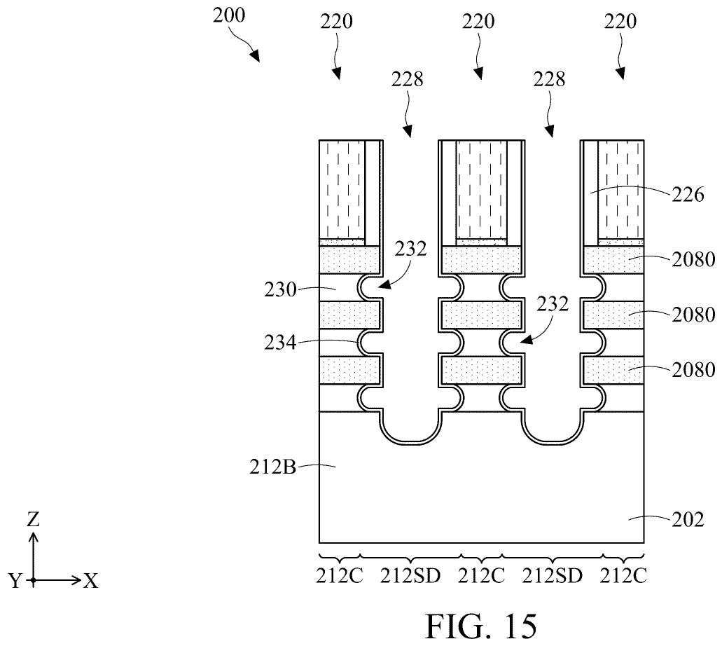

Referring to FIGS. 1 and 15, method 100 includes a block 122 where a first inner spacer layer 234 is conformally deposited over exposed surfaces of the source/drain trench 228 including the surfaces of the inner spacer recesses 232. A thickness of the first inner spacer layer 234 may be between about 0.5 nm and about 3 nm. In some embodiments, the first inner spacer layer 234 is formed of a material that has a high etching contrast with respect to the dummy layers 230, which allows the dummy layers 230 to be selectively removed later on. In some embodiments, the first inner spacer layer 234 includes metal oxide, such as polycrystalline aluminum oxide. As the dummy layer 230 is formed of silicon oxide, the removal of dummy layer 230 in a subsequent step may include use of hydrofluoric acid or hydrogen fluoride. It has been observed that crystalline or polycrystalline aluminum oxide experience slow etching by hydrofluoric acid. When the first inner spacer layer 234 includes polycrystalline aluminum oxide, it may be deposited using atomic layer deposition (ALD). In some embodiments, an anneal process may be performed after the deposition of the first inner spacer layer 234 to increase crystallinity of the first inner spacer layer 234. Because source/drain features and gate structures have not been formed at this point, the anneal process is unlikely to result in any undesirable side effect, such as change in doping profile or threshold voltage drift. In some instances, the anneal process may include an anneal temperature between about 200° C. and about 500° C. When the first inner spacer layer 234 includes polycrystalline aluminum oxide, it has a dielectric constant between about 8 and about 9.5.

In some alternative embodiments, the first inner spacer layer 234 includes a polymeric material, such as polyethylene (PE) or polypropylene (PP). While polymeric materials may be susceptible to dry etching that involves use of plasma, they can be quite resistant to acid, such as hydrofluoric acid that is used to etch the dummy layer 230. In these embodiments, in order to deposit the polymeric materials over the WIP structure 200, surfaces of the WIP structure 200 may be subject to a plasma treatment to increase the population of dangling hydroxyl bonds on the surfaces. In some instances, the plasma treatment may include use of oxygen plasma. After the surface plasma treatment, monomers of the polymeric material, such as ethylene or propylene are allowed to come in contact and react with the dangling bond in presence of at least one catalyst. In one example process, a first catalyst is first used to promote reaction between the monomers and the dangling bonds and then a second catalyst is used to promote polymerization of the monomer. When the first inner spacer layer 234 includes PE or PP, it has a dielectric constant between about 2.2 and about 2.6.

In still some alternative embodiments, the first inner spacer layer 234 includes a boron-containing dielectric material, such as boron carbon oxynitride (BCNO) or boron-doped silicon oxycarbonitride (B—SiOCN). In these embodiments, the boron contents allow the boron-containing dielectric material to be resistant to the chemistry that etches the dummy layer 230. Additionally, boron carbon oxynitride (BCNO) may have a dielectric constant between about 1.2 and about 3.7, which is advantageous in reducing parasitic capacitance. In still some alternative embodiments, the first inner spacer layer 234 includes an oxide-based dielectrics or a nitride-based dielectrics, such as silicon nitride, silicon oxide, silicon oxycarbide, silicon carbonitride, silicon oxycarbonitride, or silicon oxynitride. In some implementations, the first inner spacer layer 234 may be deposited using chemical vapor deposition (CVD) or atomic layer deposition. Notably, in some alternatively embodiments, block 122 is optional, and method 100 may skip block 122 and proceed to block 124 without forming the first inner spacer layer 234.

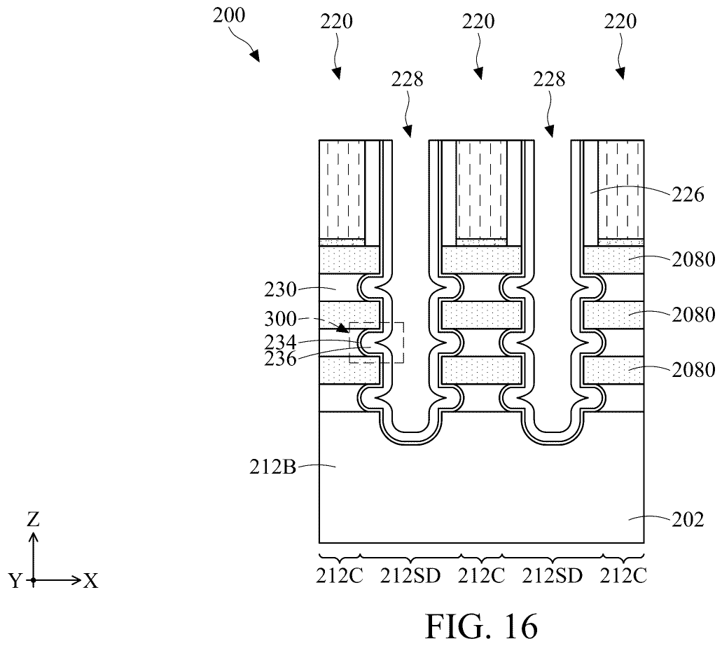

Referring to FIGS. 1 and 16, method 100 includes a block 124 where a second inner spacer layer 236 is deposited over the inner spacer recesses 232. The second inner spacer layer 236 may be deposited by a conformal deposition process, such as CVD, ALD, or the like. The conformity of deposition may be between about 50% and about 99%. The second inner spacer layer 236 may comprise a material such as silicon nitride, silicon oxide, silicon oxycarbide, silicon carbonitride, silicon oxycarbonitride, or silicon oxynitride, although any suitable material may be utilized. In some embodiments, the second inner spacer layer 236 is a low-k dielectric layer which may deposited using precursors, such as SiHₓCl_{y}R_{z} (R=CH₃, NCH₃), SiHₓCl_{y}, SiHₓ(R1)_{y}Clₓ(R2)_{z} (R1=CH, R2=NCH₃), CₓH_{y}, Nₓ/O_{y}/H_{z} and deposited at temperature between about 23° C. and about 700° C. As deposited, the second inner spacer layer 236 may include an elemental composition where C is 5-20%, N is 10-30%, O is 20-50%, and Si is 30-50%, by atomic ratio. The second inner spacer layer 236 may be a low-k dielectric layer with a k-value (dielectric constant) from about 3.0 to about 7.0. A composition of the second inner spacer layer 236 is selected to be different from the first inner spacer layer 234. Generally, when the first inner spacer layer 234 includes polycrystalline aluminum oxide, the dielectric constant of the second inner spacer layer 236 is smaller than the dielectric constant of the first inner spacer layer 234; however, when the first inner spacer layer 234 includes boron carbon oxynitride, PE, PP, or other polymeric materials, the dielectric constant of the second inner spacer layer 236 is greater than the dielectric constant of the first inner spacer layer 234; when the first inner spacer layer 234 includes boron-doped silicon oxycarbonitride, the dielectric constant of the second inner spacer layer 236 may be substantially similar to the dielectric constant of the first inner spacer layer 234. The density of the second inner spacer layer 236 can be varied from about 2 g/cm³ to about 7 g/cm³ depending on the composition. For example, in some embodiments, such as when the material is silicon oxycarbonitride, the second inner spacer layer 236 may have a dielectric constant between about 4.9 and 5.4 as deposited and may have a density between about 2.5 g/cm³ and about 2.7 g/cm³. In addition, the second inner spacer layer 236 may include trace amounts of the precursor materials (other than the primary materials), such as Cl and/or H.

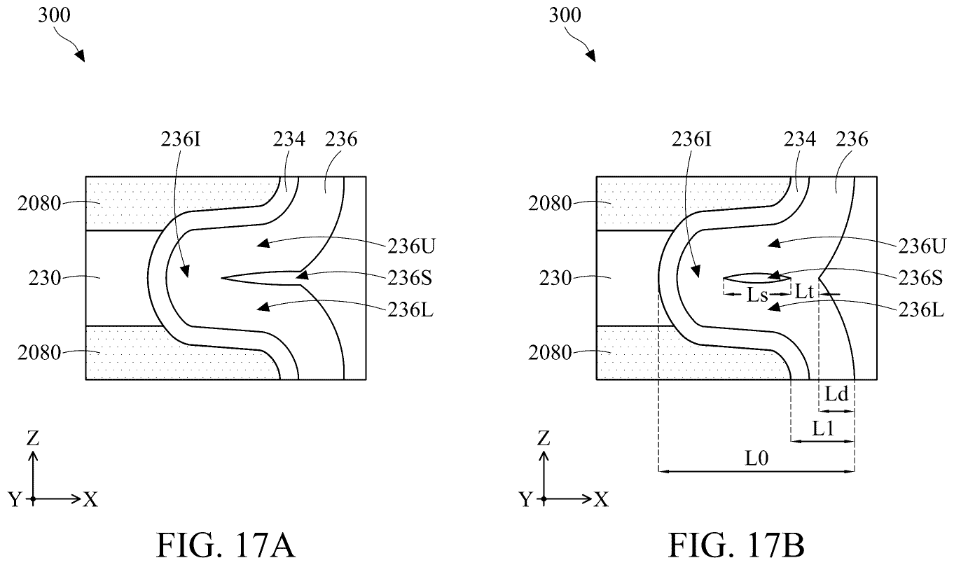

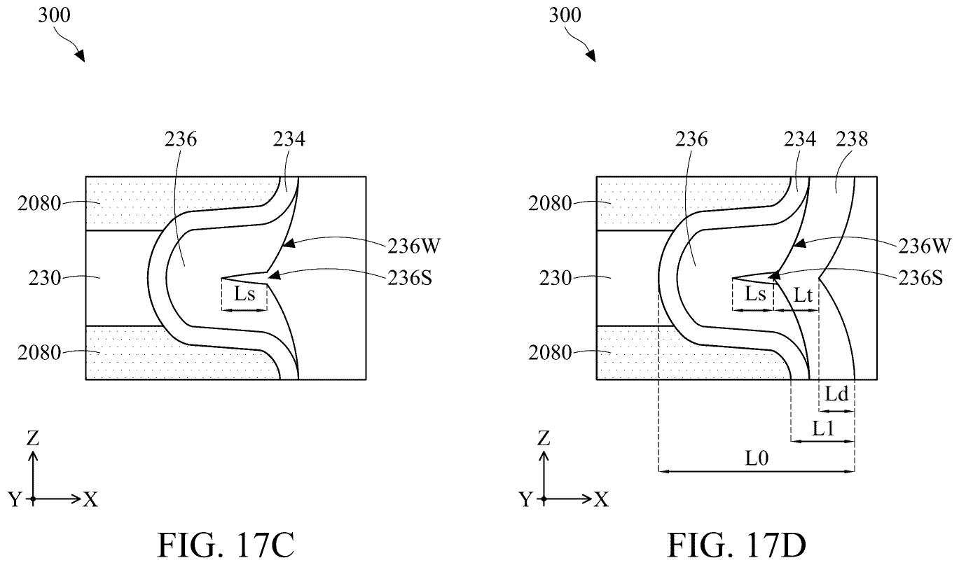

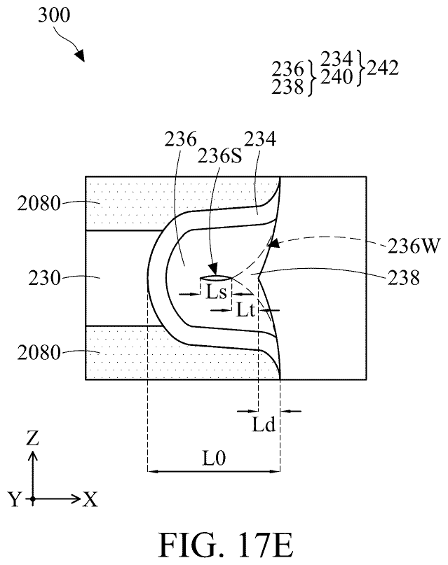

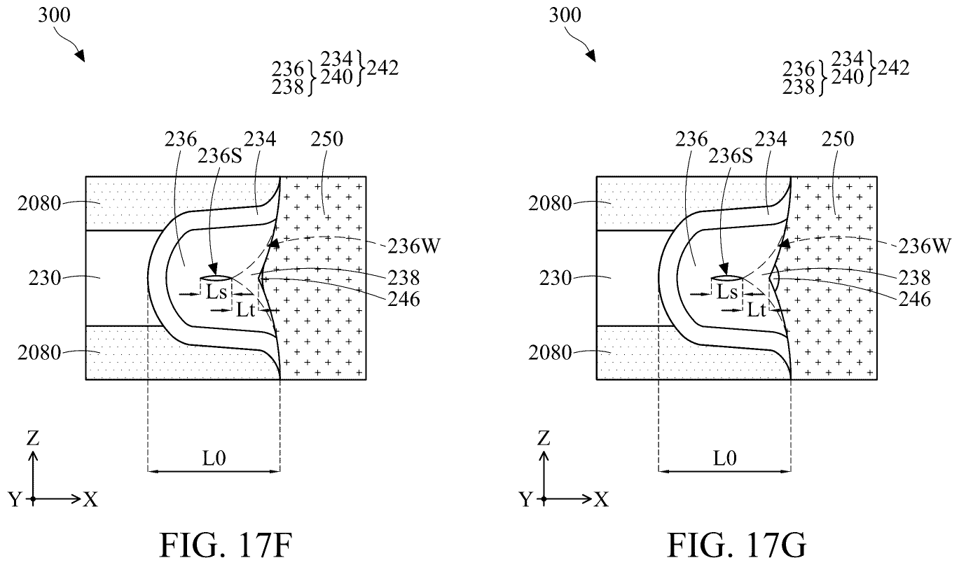

In FIG. 17A, an enlarged view of a region marked 300 in FIG. 16 during the conformal deposition process of the second inner spacer layer 236 is illustrated, in accordance with some embodiments. The deposition process of the second inner spacer layer 236 may result in a lateral or horizontal seam 236S or bird's beak opening formed between an upper portion 236U of the second inner spacer layer 236 and a lower portion 236L of the second inner spacer layer 236 and having a seam termination corresponding to a side portion 2361 of the second inner spacer layer 236. The upper portion 236U of the second inner spacer layer 236 results from the conformal deposition of the dielectric material on the exposed bottom surface of the respective upper channel member 2080. The lower portion 236L of the second inner spacer layer 236 results from the conformal deposition of the dielectric material on the exposed upper surface of the respective lower channel member 2080b. And the side portion 2361 of the second inner spacer layer 236 results from the conformal deposition of the dielectric material on the sidewall of the inner spacer recess 232. As illustrated in FIG. 17A, the seam 236S has a beaked opening.

As illustrated in FIG. 17B, as the conformal deposition continues, the thickness of the upper portion 236U and the lower portion 236L of the second inner spacer layer 236 continue to grow and eventually close the beaked opening and seal the seam 236S. In some embodiments, a lateral length Ls of the seam 236S may be between 25% and 75% of the lateral thickness L0 of the first and second inner spacer layers 234 and 236, such as about 5 nm to about 6 nm; the thickness L1, as the extra thickness of the first and second inner spacer layers 234 and 236 covering on sidewalls of the channel members 2080, may range from about 4 nm to about 6 nm; a depth Ld of a dishing profile of the sidewall of the second inner spacer layer 236 may be between about 1 nm and about 2 nm; and a lateral distance Lt between the seam 236S and the apex point of the dishing, which is also the thickness of the second inner spacer layer 236 sealing the seam 236S, may be between about 0.5 nm and about 1 nm.

Referring to FIGS. 1 and 17C, method 100 includes a block 126 where the second inner spacer layer 236 is etched back in a first etch back process (also referred to as first trimming process). In some embodiments, the first etch back process at block 126 may include a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In some embodiment, the dry etch process is anisotropic to some extent. In the illustrated embodiment, the second inner spacer layer 236 is etched back to expose the first inner spacer layer 234. Alternatively, the second inner spacer layer 236 and the first inner spacer layer 234 are etched back to expose sidewalls of the channel members 2080. The first etch back process opens the seam 236S. The lateral length Ls of the seam 236S is reduced to about 0.2 nm to about 1.2 nm. At the conclusion of block 126, the recessed second inner spacer layer 236 has a sidewall 236W that is laterally outward facing to some extent. The sidewall 236W may resemble a V-shape with the opening laying aside.

In some embodiments, at the conclusion of block 126, method 100 may optionally include a cleaning process to clean surfaces of the WIP structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The cleaning process may further enlarge the opening and volume of the remaining portion of the seam 236S.

Referring to FIGS. 1 and 17D, method 100 includes a block 128 where a third inner spacer layer 238 is deposited over the sidewall 236W of the second inner spacer layer 236. The third inner spacer layer 238 seals the seam 236S. The third inner spacer layer 238 may be deposited by a conformal deposition process, such as CVD, ALD, or the like. The conformity of deposition may be between about 50% and about 99%. Unlike the deposition of the second inner spacer layer 236 that occurs in a narrow area inside the inner spacer recesses 232, the deposition of the third inner spacer layer 238 starts from the laterally outward facing sidewall 236W and grows towards a relatively open space in the source/drain trench 228. Accordingly, the third inner spacer layer 238 is substantially seam fee. The ranges of the thickness L0, thickness L1, and the dishing depth Ld may be similar to those ranges as described with reference to FIG. 17B. However, the lateral length Ls of the seam 236S is significantly reduced, and the lateral distance Lt is significantly enlarged. The reduced length Ls of the seam 236S and the enlarged distance Lt between the seam 236S and the apex point of the dishing safeguards the seam 236S from being accidently exposed in subsequent etching and/or cleaning processes. Otherwise, if the seam 236S is opened in subsequent etching and/or cleaning processes, etchant chemicals and/or cleaning solvents will flow into the seam 236S and the etch rate will be significantly accelerated in the vicinity of the seam 236S. Consequently, the resultant inner spacers would be much thinner than expected. Insufficient thickness of the inner spacers may lead to higher parasitic capacitance and even cause a short between a gate structure and an epitaxial source/drain feature if the thin inner spacers are broken through in a gate replacement process. The gate replacement process would be discussed in further detail later on with respect to block 134.

The third inner spacer layer 238 may comprise a material such as silicon nitride, silicon oxide, silicon oxycarbide, silicon carbonitride, silicon oxycarbonitride, or silicon oxynitride, although any suitable material may be utilized. In some embodiments, a composition of the third inner spacer layer 238 is selected to be different from the first inner spacer layer 234. The composition of the third inner spacer layer 238 may be the same or different from the second inner spacer layer 236. When the third inner spacer layer 238 and the second inner spacer layer 236 have different material compositions, the sidewall 236W as an interface between the third inner spacer layer 238 and the second inner spacer layer 236 may be discernable. When the third inner spacer layer 238 and the second inner spacer layer 236 have the same material composition, the sidewall 236W as the interface between the third inner spacer layer 238 and the second inner spacer layer 236 may be discernable or undiscernible, depending on particular deposition parameters applied at block 128. In some embodiments, the composition of the third inner spacer layer 238 is selected to be the same as the first inner spacer layer 234, but different from the second inner spacer layer 236. For example, the third inner spacer layer 238 may have a higher dielectric constant and/or a higher etching resistance than the second inner spacer layer 236, which helps resisting etchants' erosion from the direction of the source/drain trenches 228 in subsequent steps.

Referring to FIGS. 1 and 17E, method 100 includes a block 130 where the third inner spacer layer 238 is etched back in a second etch back process (also referred to as second trimming process). In some embodiments, the second etch back process at block 130 may include a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In some embodiment, the dry etch process is anisotropic to some extent. If the first inner spacer layer 234 is not yet etched back to expose sidewalls of the channel members 2080 after the first etch back process, the first inner spacer layer 234 would also be etched back together with the third inner spacer layer 238 during the second etch back process to expose the sidewalls of the channel members 2080.

The remaining portions of the first inner spacer layer 234, the second inner spacer layer 236, and the third inner spacer layer 238 collectively define inner spacers 242. The inner spacers 242 can be considered to have the first inner spacer layer 234 as a liner (also referred to as liner 234) and the second and third inner spacer layers 236 and 238 as the bulk dielectric portion 240 surrounded by the liner 234. The bulk dielectric portion 240 includes the second inner spacer layer 236 as the first sub-layer (also referred to as first sub-layer 236) and the third inner spacer layer 238 as the second sub-layer (also referred to as second sub-layer 238), which is surrounded by (embedded in) the first sub-layer 236. Depending on the material compositions of the inner spacer layer 236 and the third inner spacer layer 238 and their respective deposition methods, the sidewall 236W at the interface between them may be discernible or indiscernible. In some examples, the bulk dielectric portion 240 is considered to have a single dielectric material if the inner spacer layers 236 and 238 have the same material compositions. In furtherance of some examples, the liner 234 also has the same material composition, and the entire inner spacer 242 is considered as having a single dielectric material. In the depicted embodiment, the inner spacer 242 has a hat-shape profile that includes a dome-shape portion vertically stacked between two adjacent channel members 2080 and a brim-shape portion (mainly liner 234) vertically disposed partially on the sidewalls of the channel members 2080.

Still referring to FIG. 17E, the seam 236S is defined in the second inner spacer layer 236, yet it is laterally capped (or sealed) by the third inner spacer layer 238. In some embodiments, the thickness L0 of the inner spacers 242 is reduced to about 1 nm to about 10 nm; the length Ls of the seam 236S is reduced to about 0.2 nm to about 1.2 nm; the dishing depth Ld is reduced to between about 0.01 nm and about 1 nm; and the lateral distance Lt between the seam 236S and the apex point of the dishing, which is also the thickness of the third inner spacer layer 238 sealing the seam 236S, is enlarged to between 1 nm and about 5 nm. The now much shallower dishing depth Ld reduces amount of etchant chemicals and/or cleaning solvents in subsequent etching and/or cleaning processes to accumulate in the dishing; the now much thicker lateral distance Lt also effectively prevents the seam 236S from being accidently opened in subsequent etching and/or cleaning processes.

In some embodiments, at conclusion of block 130, method 100 may optionally include a cleaning process to clean surfaces of the WIP structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment.

Reference is now made to FIGS. 17F and 17G, which show the region 300 after the source/drain feature 250 is formed in the source/drain trench 228. The formation of the source/drain feature 250 will be explained in further detail with respect to block 132 later on. FIG. 17F and FIG. 17G each illustrate a void 246 trapped between the inner spacer 242 and the source/drain feature 250 due to the dishing profile. In FIG. 17F, the sidewall of the source/drain feature 250 in the void 246 has a convex profile, bending towards the third inner spacer layer 238. Alternatively, as depicted in FIG. 17G, the sidewall of the source/drain feature 250 in the void 246 may have a concave profile, bending away from the third inner spacer layer 238. This variation depends on the growth rate of the source/drain feature 250 during its formation, specifically on how quickly the portions of the source/drain feature 250 grown from the sidewalls of the adjacent two channel members 2080 merge. As discussed above, the dishing depth Ld has been reduced to a range in about 0.01 nm to about 1 nm, and size of the void 246 is roughly at the same scale. State differently, the size of the void 246 is significantly reduced through the “de-seaming” process as illustrated in FIGS. 17A-E.

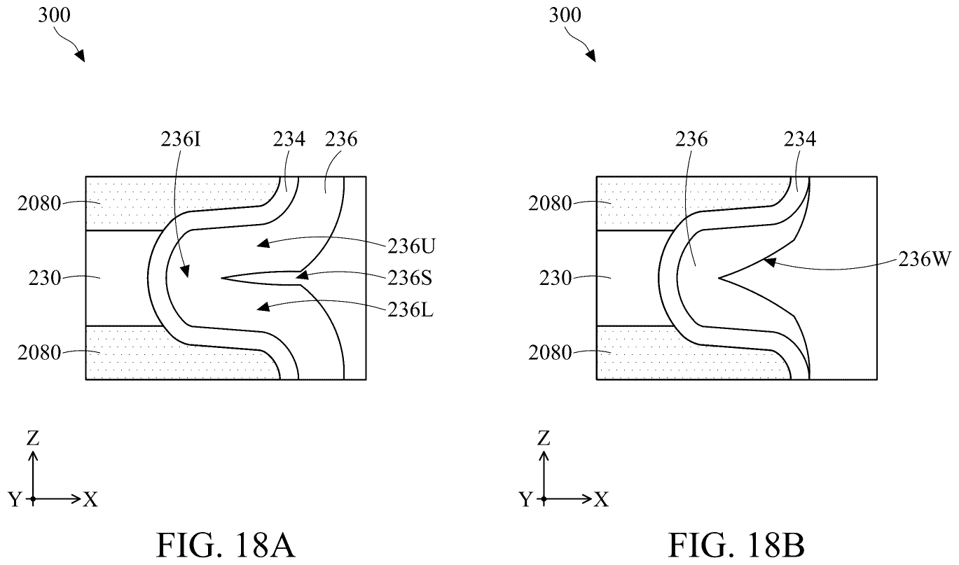

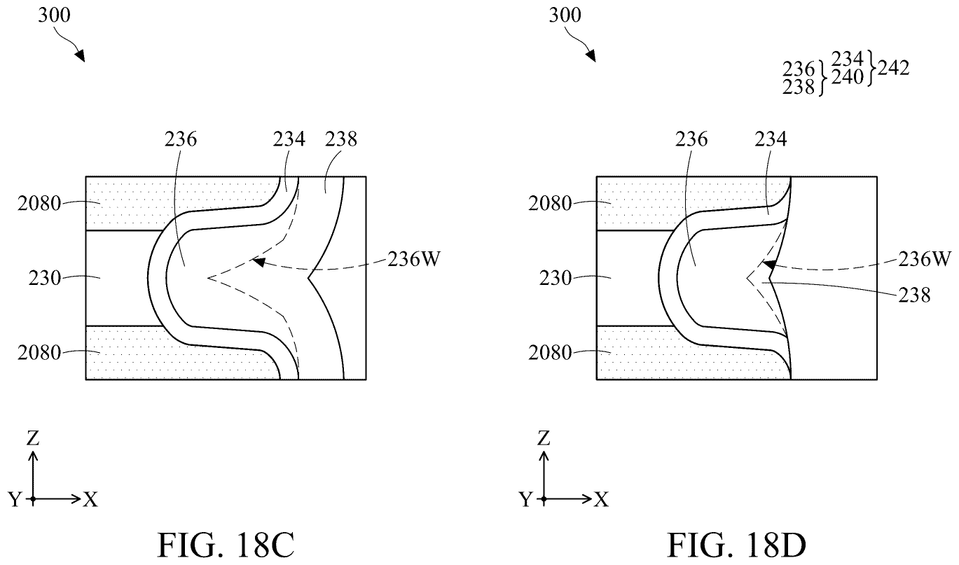

An alternative “de-seaming” process is illustrated in FIGS. 18A-E. FIG. 18A is substantially similar to FIG. 17A, in which the deposition process of the second inner spacer layer 236 results in a lateral or horizontal seam 236S or bird's beak opening formed between an upper portion 236U of the second inner spacer layer 236 and a lower portion 236L of the second inner spacer layer 236 and having a seam termination corresponding to a side portion 2361 of the second inner spacer layer 236. Yet, the deposition of the second inner spacer layer 236 stops at FIG. 18A, which is before closing the beaked opening, and method 100 proceeds to block 126 to etch back the second inner spacer layer 236 in a first etch back process (also referred to as first trimming process), as shown in FIG. 18B. The first etch back process opens up the bird's beak opening to form a sidewall 236W that is laterally outward facing to some extent. Method 100 may optionally perform a cleaning process to clean surfaces of the WIP structure 200. Subsequently, method 100 proceeds to block 128 to deposit the third inner spacer layer 238. Since the opening of the bird's beak diminishes the seam 236S, there is no seam remaining inside the second and third inner spacer layers 236 and 238, as shown in FIG. 18C. Method 100 then proceeds to block 130 to etch back the third inner spacer layer 238 in a second etch back process (also referred to as the second trimming process), as shown in FIG. 18D. If the first inner spacer layer 234 is not yet etched back to expose sidewalls of the channel members 2080 after the first etch back process, the first inner spacer layer 234 would also be etched back together with the third inner spacer layer 238 during the second etch back process to expose the sidewalls of the channel members 2080. Thereafter, method 100 may optionally perform a cleaning process to clean surfaces of the WIP structure 200. At the conclusion of block 130, the remaining portions of the first inner spacer layer 234, the second inner spacer layer 236, and the third inner spacer layer 238 collectively define inner spacers 242. In the depicted embodiment as shown in FIG. 18D, the inner spacer 242 has a hat-shape profile that includes a dome-shape portion vertically stacked between two adjacent channel members 2080 and a brim-shape portion vertically disposed partially on the sidewalls of the channel members 2080. In some embodiments, the sidewall of the inner spacer 242 has a dishing profile with a dishing depth ranging from about 0.01 nm to about 1 nm. FIG. 18E further shows the region 300 after a source/drain feature 250 is formed in the source/drain trench 228. The formation of the source/drain feature 250 will be explained in further detail with respect to block 132 later on. Compared with the embodiment depicted in either FIG. 17F or FIG. 17G, one difference is that in FIG. 18E the inner spacer 242 is seam free, and there is no void trapped between the inner spacer 242 and the source/drain feature 250 due to the early expanding the aperture of the bird's beak opening.

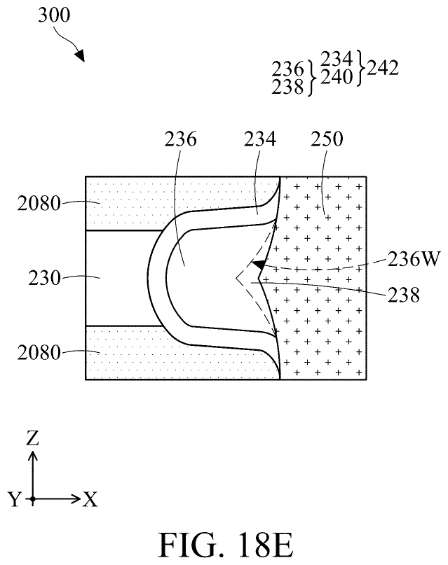

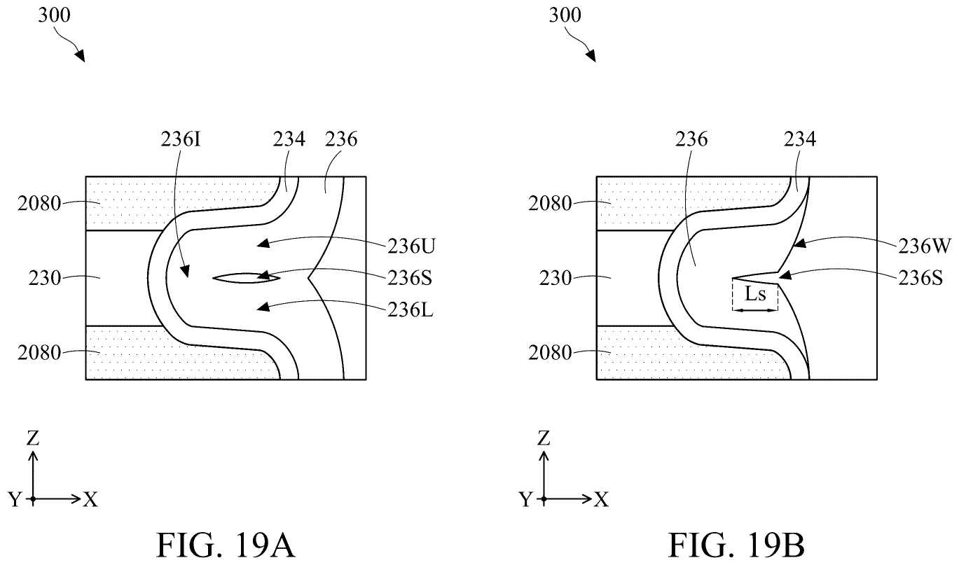

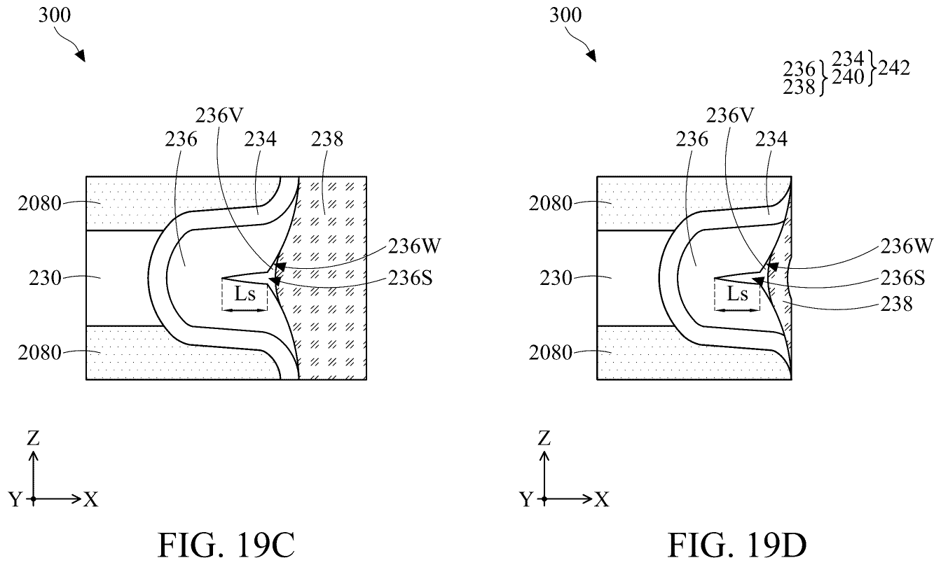

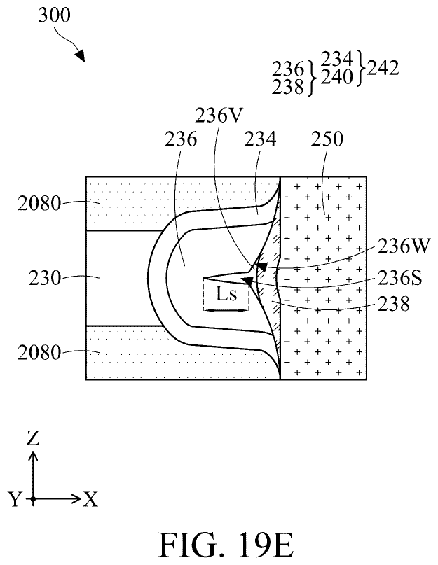

Another alternative “de-seaming” process is illustrated in FIGS. 19A-E. FIG. 19A is substantially similar to FIG. 17B, in which as the conformal deposition continues, the thickness of the upper portion 236U and the lower portion 236L of the second inner spacer layer 236 continue to grow and eventually close the beaked opening and seal the seam 236S. Method 100 proceeds to block 126 to etch back the second inner spacer layer 236 in a first etch back process (also referred to as first trimming process), as shown in FIG. 19B. The first etch back process shrinks the length of the seam 236S and creates the outward facing sidewall 236W. Thereafter, method 100 may optionally perform a cleaning process to clean surfaces of the WIP structure 200. Subsequently, the third inner spacer layer 238 is formed. Different from the embodiments depicted in FIG. 17D or FIG. 18C, the third inner spacer layer 238 may be formed after a bottom epitaxial feature of the source/drain feature 250 is formed in the bottom of the source/drain trench 228. The formation of the bottom epitaxial feature of the source/drain feature 250 will be explained in further detail with respect to block 132 later on. The third inner spacer layer 238 caps the seam 236S and also traps a void 236V between the second and third inner spacer layers 236 and 238, as shown in FIG. 19C. Method 100 then proceeds to block 130 to etch back the third inner spacer layer 238 in a second etch back process (also referred to as the second trimming process), as shown in FIG. 19D. If the first inner spacer layer 234 is not yet etched back to expose sidewalls of the channel members 2080 after the first etch back process, the first inner spacer layer 234 would also be etched back together with the third inner spacer layer 238 during the second etch back process to expose the sidewalls of the channel members 2080. Thereafter, method 100 may optionally perform a cleaning process to clean surfaces of the WIP structure 200. At the conclusion of block 130, the remaining portions of the first inner spacer layer 234, the second inner spacer layer 236, and the third inner spacer layer 238 collectively define inner spacers 242. In the depicted embodiment as shown in FIG. 19D, the inner spacer 242 has a hat-shape profile that includes a dome-shape portion vertically stacked between two adjacent channel members 2080 and a brim-shape portion vertically disposed partially on the sidewalls of the channel members 2080. In some embodiments, the sidewall of the inner spacer 242 has a dishing profile with a dishing depth ranging from about 0.01 nm to about 1 nm. FIG. 19E further shows the region 300 after a main epitaxial feature of the source/drain feature 250 is formed in the source/drain trench 228. The formation of the main epitaxial feature of the source/drain feature 250 will be explained in further detail with respect to block 132 later on. Compared with the embodiment depicted in FIG. 17F, one difference is that in FIG. 19E the inner spacer 242 includes a seam 236S with a reduced length and a void 236V adjoined the seam 236S, while it is void free between the inner spacer 242 and the source/drain feature 250. Since the third inner spacer layer 238 is formed after a portion of the source/drain feature 250 is already formed, the third inner spacer layer 238 avoids experiencing some of the etching and cleaning processes associated with the formation of the source/drain feature 250, and thus the entire inner spacer 242 has a lower risk of being etched through even there are the seam 236S and the void 236V trapped inside.

Referring to FIGS. 1, 20 and 21, method 100 includes a block 132 where a source/drain feature 250 is formed over the source/drain region 212SD, after the formation of the inner spacers 242 as shown in FIG. 17E, FIG. 18D, or FIG. 19D at the conclusion of block 130. While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

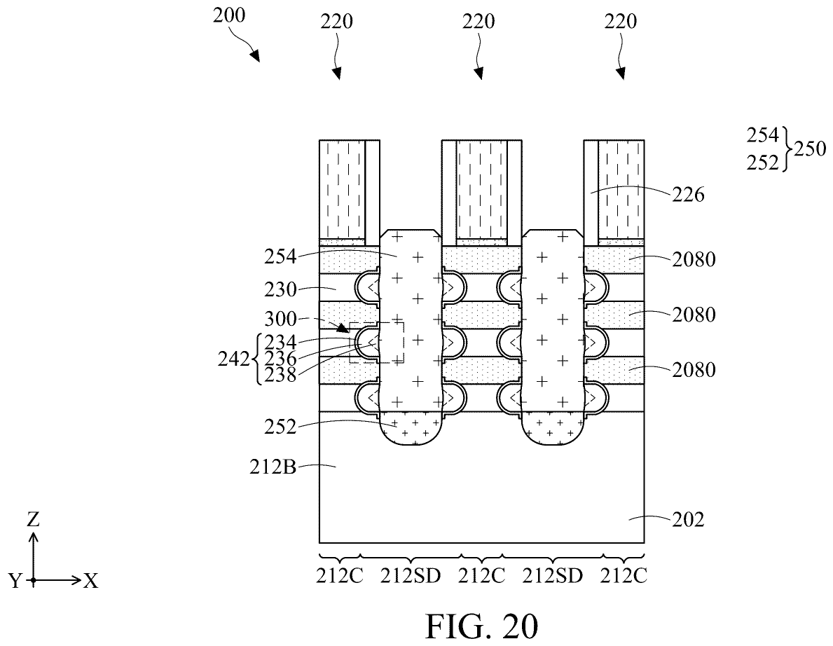

Reference is made to FIG. 20. In some embodiments, a source/drain feature 250 includes a bottom epitaxial feature 252 and a main epitaxial feature 254 over the bottom epitaxial feature 252. The source/drain feature 250 may be n-type or p-type. When the source/drain feature 250 is n-type, the bottom epitaxial feature 252 may include undoped silicon (Si) or undoped silicon germanium (SiGe) and the main epitaxial feature 254 may include silicon (Si) and an n-type dopant, such as phosphorus (P), arsenic (As), antimony (Sb), or a combination thereof. When the source/drain feature 250 is p-type, the bottom epitaxial feature 252 may include undoped silicon (Si) or undoped silicon germanium (SiGe) and the main epitaxial feature 254 may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom epitaxial feature 252 may include a counter dopant to reduce leakage into the bulk substrate 202. For example, the bottom epitaxial feature 252 in the n-type source/drain feature 250 may include a p-type dopant, such as boron (B). For another example, the bottom epitaxial feature 252 in the p-type source/drain feature 250 may include an n-type dopant, such as phosphorus (P), arsenic (As), or antimony (Sb). The source/drain feature 250 may be formed using vapor-phase epitaxy (VPE), ultra-high vacuum CVD (UHV-CVD), or molecular beam epitaxy (MBE). Doping of the source/drain features 250 may be achieved with in-situ doping.

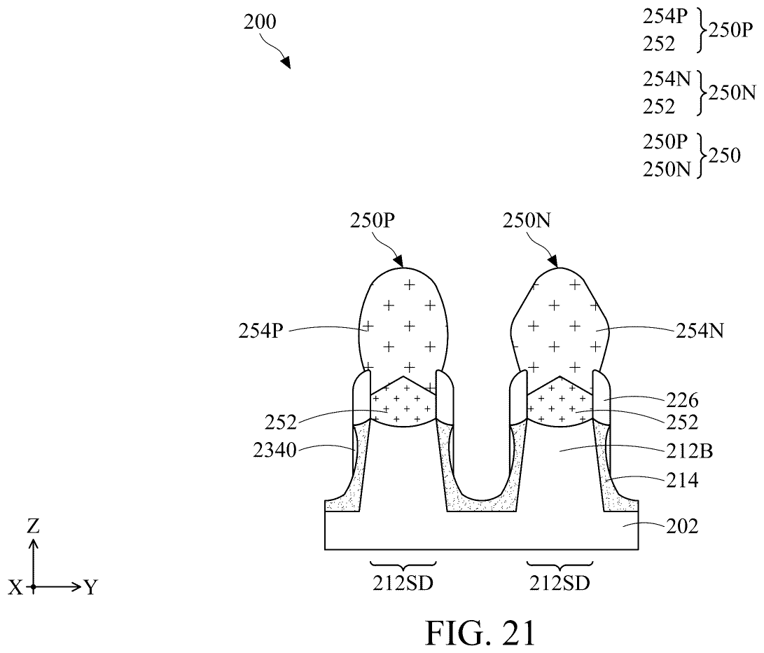

Reference is made to FIG. 21, which includes a fragmentary cross-sectional view across two adjacent source/drain regions 212SD. In some embodiments represented in FIG. 20, an n-type source/drain feature 250N may be adjacent a p-type source/drain feature 250P. The n-type source/drain feature 250N includes the bottom epitaxial feature 252 and an n-type main epitaxial feature 254N. The n-type main epitaxial feature 254N may include silicon (Si) and an n-type dopant, such as phosphorus (P), arsenic (As), or antimony (Sb). The p-type source/drain feature 250P includes the bottom epitaxial feature 252 and a p-type main epitaxial feature 254P. The p-type main epitaxial feature 254P may include silicon germanium (SiGe) and a p-type dopant, such as boron (B). Each of the n-type source/drain feature 250N and the p-type source/drain feature 250P may be in direct contact with a top surface of the base fin structure 212B and a sidewall of the gate spacer layer 226. For ease of illustration and description, the n-type source/drain feature 250N and the p-type source/drain feature 250P may be collectively referred to as the source/drain feature 250, as in FIG. 20. As shown in FIG. 21, the etch back at previous block 130 may not completely remove a sidewall portion 2340 of the first inner spacer layer 234 along sidewalls of the isolation feature 214.

At the conclusion of block 132, the features in the region 300 as detailed in either FIG. 17F, FIG. 17G, FIG. 18E, or FIG. 19E are formed. As discussed above, in some embodiments, the formation of the source/drain feature 250 may be performed after the formation of all the dielectric layers (inner spacer layers 234, 236, and 238) in the inner spacers 242; alternatively, in some embodiments, the formation of the bottom epitaxial feature 252 is after the formation of the first inner spacer layer 234 and the second inner spacer layer 236, the formation of the third inner spacer layer 238 is after the formation of the bottom epitaxial feature 252, and the formation of the main epitaxial feature 254 is after the formation of the third inner spacer layer 238.

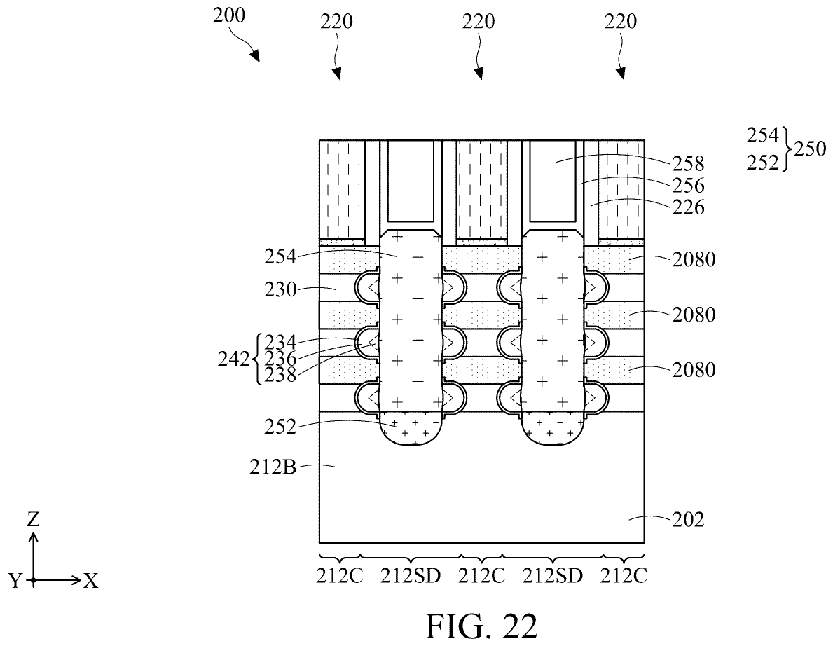

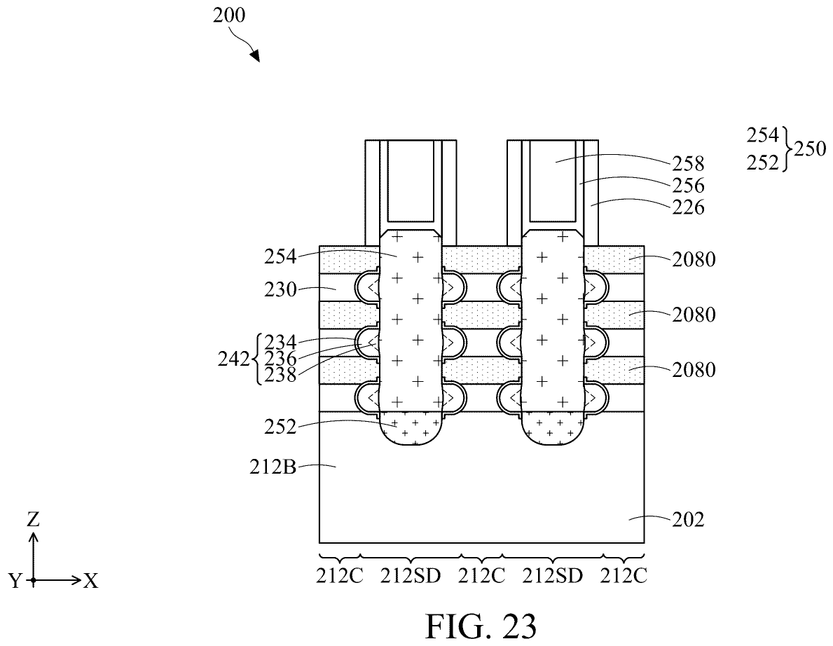

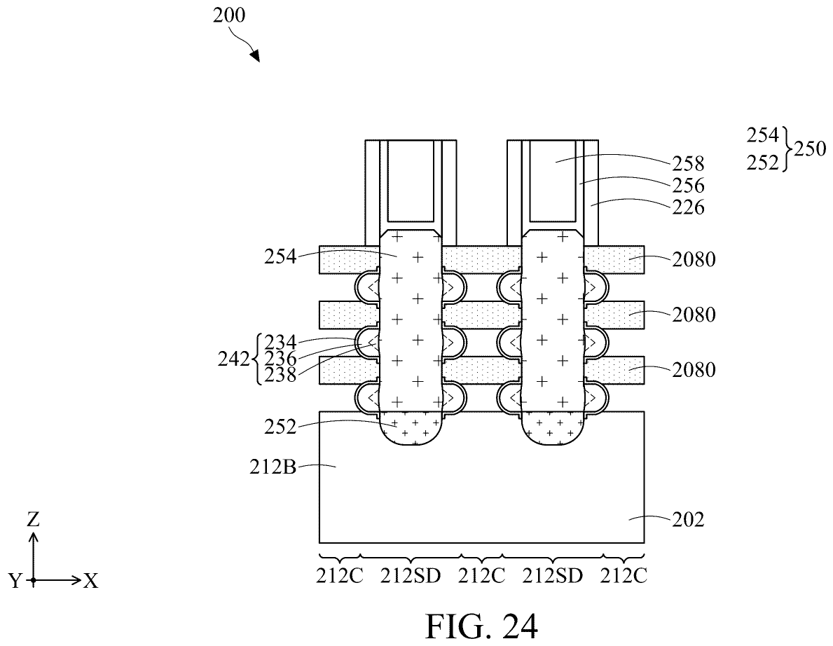

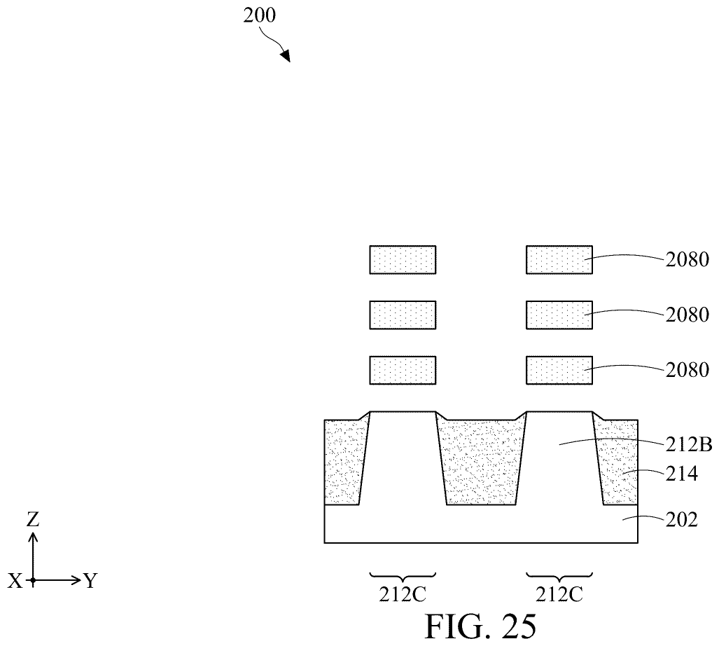

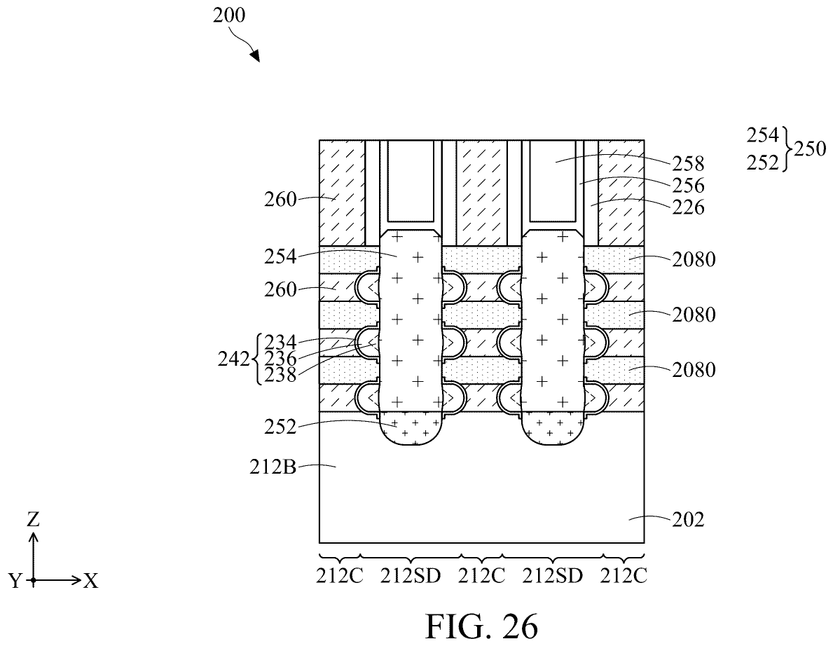

Referring to FIGS. 1 and 22-26, method 100 includes a block 134 where the dummy gate stack 220 and the dummy layer 230 are replaced with a gate structure 260 (also referred to as metal gate structure 260). Operations at block 134 may include deposition of a contact etch stop layer (CESL) 256 over the source/drain features 250 (shown in FIG. 22), deposition of an interlayer dielectric layer 258 over the CESL 256 (shown in FIG. 22), removal of the dummy gate stack 220 (shown in FIG. 23), removal of the dummy layer 230 (shown in FIGS. 24 and 25), and deposition of the gate structure 260 to wrap around each of the channel members 2080 (shown in FIG. 26). Referring to FIG. 22, the CESL 256 is deposited over the WIP structure 200, including over the source/drain feature 250. The CESL 256 may include silicon nitride or aluminum nitride. In some implementations, the CESL 256 may be deposited using CVD or atomic layer deposition (ALD). The ILD layer 258 is then deposited over the CESL 256. In some embodiments, the ILD layer 258 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 258 may be deposited using CVD, flowable CVD (FCVD), spin-on coating, or a suitable deposition technique. After the deposition of the ILD layer 258, the WIP structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

After the removal of the dummy gate stack 220, the dummy layer 230 in the channel region 212C is exposed. A separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As described above, the selective etch of the dummy layer 230 etches the first inner spacer layer 234 at a much smaller rate. After the selective removal of the dummy layer 230, the channel members 2080 in the channel region 212C are once again exposed as shown in FIGS. 24 and 25.

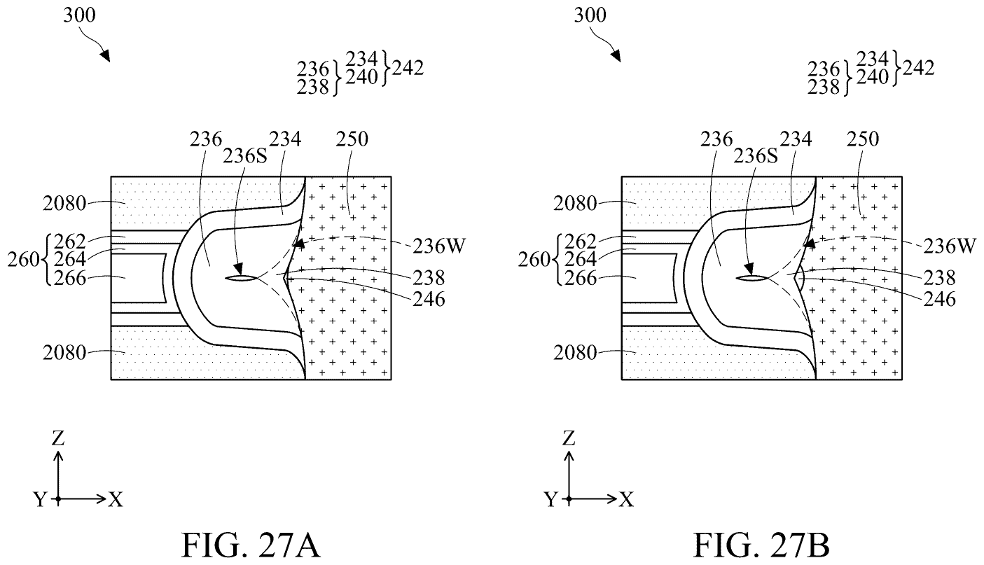

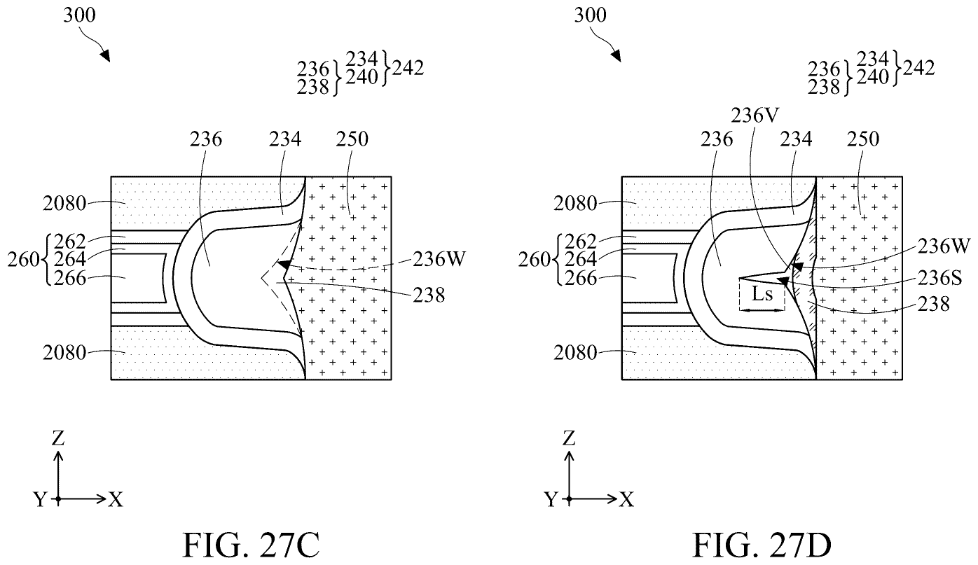

After the release of the channel members 2080, the gate structure 260 is formed to wrap around each of the channel members 2080 as shown in FIG. 26. FIGS. 27A-D further illustrate various embodiments of the region 300 after the gate replacement process with respect to intermediate structures depicted in FIGS. 17F, 17G, 18E, and 19E, respectively. While not explicitly shown in FIG. 26 (but shown in FIGS. 27A-D), the gate structure 260 includes an interfacial layer 262 interfacing the channel members 2080 and the substrate 202 in the channel region 212C, a gate dielectric layer 264 over the interfacial layer 262, and a gate electrode layer 266 over the gate dielectric layer 264. The interfacial layer 262 may include a dielectric material such as silicon oxide, hafnium silicate, or silicon oxynitride. The interfacial layer 262 may be formed by chemical oxidation, thermal oxidation, atomic layer deposition (ALD), chemical vapor deposition (CVD), and/or other suitable method. If the interfacial layer 262 is formed in an oxidation process, the interfacial layer 262 may be selectively formed on exposed semiconductor surfaces but not on dielectric surfaces. State differently, the interfacial layer 262 may be free of contact with sidewalls of the inner spacers 242 (except for an end portion of the interfacial layer 262 in a corner region where the channel members 2080 intersect the inner spacers 242).

The gate dielectric layer 264 may include a high-k dielectric material, such as hafnium oxide. Alternatively, the gate dielectric layer 264 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer 264 may be formed by ALD, physical vapor deposition (PVD), CVD, oxidation, and/or other suitable methods. The gate dielectric layer 264 also covers sidewalls of the inner spacers 242.

The gate electrode layer 266 of the gate structure 260 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 266 may include titanium nitride (TiN), titanium aluminum (TiAl), titanium aluminum nitride (TiAIN), tantalum nitride (TaN), tantalum aluminum (TaAl), tantalum aluminum nitride (TaAIN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 266 may be formed by ALD, PVD, CVD, e-beam evaporation, or other suitable process. In various embodiments, a CMP process may be performed to remove excessive metal, thereby providing a substantially planar top surface of the gate structure 260. The gate structure 260 includes portions that interpose between channel members 2080 in the channel region 212C. In some embodiments, the gate structure 260 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

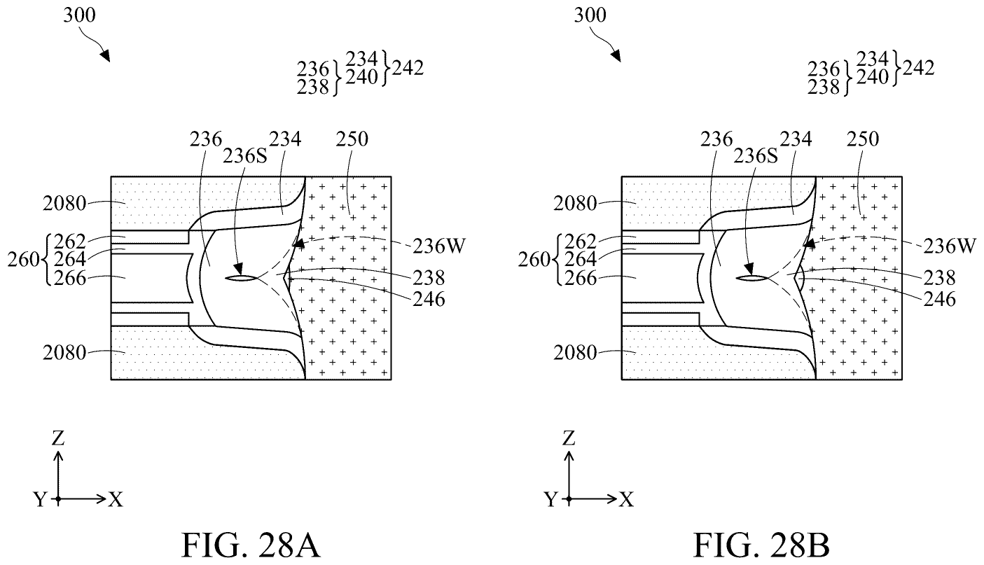

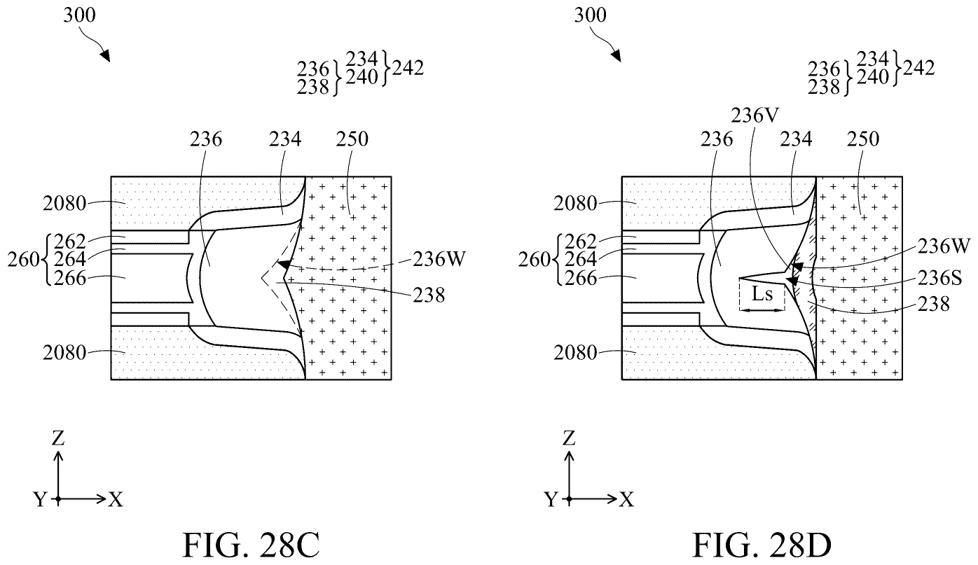

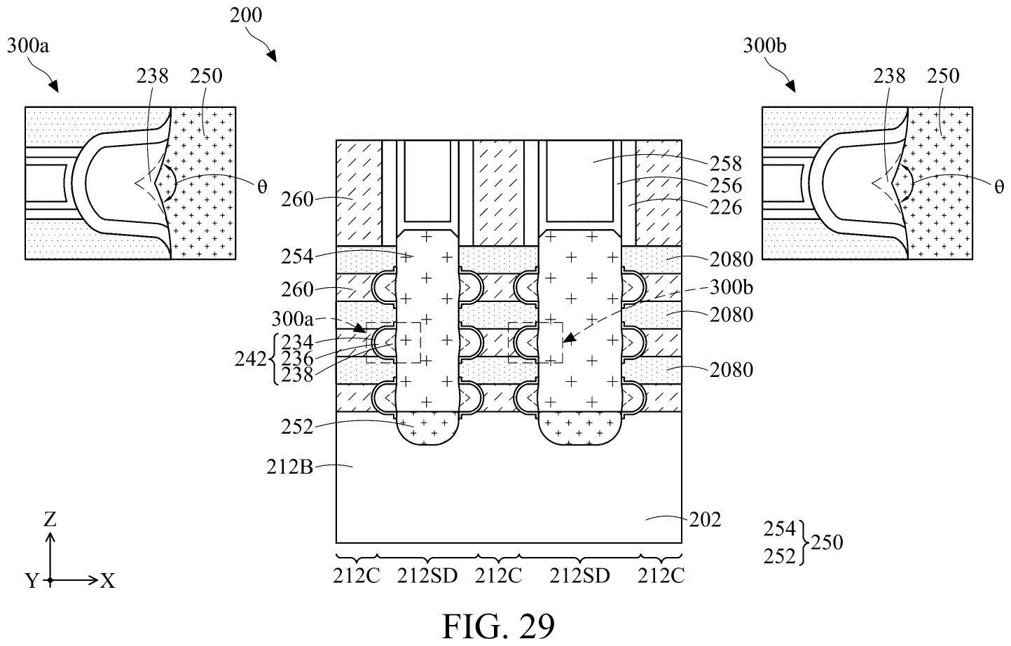

Reference is made to FIGS. 28A-D, which illustrate alternative embodiments of the region 300 after the gate replacement process with respect to intermediate structures depicted in FIGS. 17F, 17G, 18E, and 19E, respectively, given the scenario that inner spacers 242 suffer from etching loss during the removal of the dummy layer 230. If the dielectric material selected for the first inner spacer layer 234 exhibits limited etching contrast to the dummy layer 230, or the dielectric material selected for the first inner spacer layer 234 is similar or the same as the second inner spacer layer 236, or the formation of the first inner spacer layer 234 is skipped in some embodiments, the removal of the dummy layer 230 may break through the first inner spacer layer 234 and etch into the second inner spacer layer 236. Yet, due to the “de-seaming” process discussed above, the size of the seam 236S has been significantly reduced or even eliminated, which leaves a sufficiently thick inner spacer interposing the source/drain feature 250 and the gate structure 260 even if the inner spacers 242 suffer from further etching loss during the gate replacement process. Further, the reduced dishing depth of the dishing profile of the sidewall of the third inner spacer layer 238 also help reducing and eliminating the void trapped between the sidewall of the third inner spacer layer 238 and the respective source/drain feature 250. Notably, the angle θ formed between two edges of the dishing may vary due to the loading effect during the etching back of the inner spacer layer 238. As shown in FIG. 29, which illustrate a WIP structure 200 having a dense region with narrower source/drain regions 212SD and a sparse region with wider source/drain regions 212SD, more etchants would accumulate in the wider source/drain regions 212SD and create a smaller angle θ. That is, the angle θ in the region 300a that resides in the dense region may be larger than the other angle θ in the region 300b that resides in the sparse region.

Embodiments of the present disclosure advantageously include a “de-seaming process” during the formation of the inner spacers. By reducing or eliminating seams within the inner spacers, the process prevents accelerated etching rates near seams, thus preserving sufficient thickness of the inner spacers. This reduces the risk of gate protrusion from occurring and avoids shorts between the gate structure and the epitaxial source/drain features. The parasitic capacitance in the resultant device is also suppressed due to the sufficient thickness of the inner spacers.

In one exemplary aspect, the present disclosure is directed to a method. The method includes forming over a substrate a stack that includes channel layers interleaved by sacrificial layers, patterning the stack to form a fin-shaped structure, forming a dummy gate stack over a channel region of the fin-shaped structure, depositing a gate spacer layer over the dummy gate stack, after the depositing of the gate spacer layer, recessing a source/drain region of the fin-shaped structure, selectively removing the sacrificial layers in the channel region to release the channel layers as channel members, depositing a dummy layer in space between the channel members, selectively and partially recessing the dummy layer to form inner spacer recesses; depositing a first dielectric layer in the inner spacer recesses, etching back the first dielectric layer, after the etching back of the first dielectric layer, depositing a second dielectric layer over the first dielectric layer, etching back the second dielectric layer to form inner spacers in the inner spacer recesses, the inner spacers including at least the first dielectric layer and the second dielectric layer, forming a source/drain feature over the source/drain region, removing the dummy gate stack, removing the dummy layer, and forming a gate structure to wrap around each of the channel members. In some embodiments, the depositing of the first dielectric layer traps a seam inside the first dielectric layer. In some embodiments, the etching back of the first dielectric layer opens the seam. In some embodiments, the depositing of the second dielectric layer seals the seam. In some embodiments, the depositing of the first dielectric layer formed a beaked opening, and the etching back of the first dielectric layer expands an aperture of the beaked opening. In some embodiments, the depositing of the second dielectric layer fully fills the expanded beaked opening with the second dielectric layer with no seam trapped therein. In some embodiments, after the etching back of the second dielectric layer, a sidewall of the second dielectric layer has a dishing, and the forming of the source/drain feature traps a void between the sidewall of the second dielectric layer and the source/drain feature. In some embodiments, after the etching back of the second dielectric layer, a sidewall of the second dielectric layer has a dishing, and the forming of the source/drain feature fully fills the dishing with no void trapped between the sidewall of the second dielectric layer and the source/drain feature. In some embodiments, the method further includes prior to the depositing of the first dielectric layer, depositing a dielectric liner in the inner spacer recesses. The first dielectric layer is deposited on the dielectric liner, and the inner spacers include the dielectric liner, the first dielectric layer, and the second dielectric layer. In some embodiments, the forming of the source/drain feature includes prior to the depositing of the second dielectric layer forming a bottom portion of the source/drain feature, and after the etching back of the second dielectric layer forming a top portion of the source/drain feature.

In another exemplary aspect, the present disclosure is directed to a method. The method includes forming a fin-shaped structure protruding from a substrate, forming a dummy gate stack across the fin-shaped structure, depositing a gate spacer layer over the dummy gate stack, after the depositing of the gate spacer layer, recessing a region of the fin-shaped structure to form a trench, forming inner spacer recesses on sidewalls of fin-shaped structure facing the trench, depositing a first dielectric layer in the inner spacer recesses, etching back the first dielectric layer, forming a first epitaxial feature in a bottom portion of the trench, after the forming of the first epitaxial feature, depositing a second dielectric layer on the first dielectric layer, etching back the second dielectric layer to form inner spacers in the inner spacer recesses, after the etching back of the second dielectric layer, forming a second epitaxial feature in a top portion of the trench, and replacing the dummy gate stack with a metal gate structure, the inner spacers interposing the metal gate structure and the second epitaxial feature. In some embodiments, the depositing of the first dielectric layer traps a seam inside the first dielectric layer, and the etching back of the first dielectric layer opens the seam. In some embodiments, the depositing of the second dielectric layer traps a void between the first dielectric layer and the second dielectric layer. In some embodiments, the void is connected to the seam. In some embodiments, after the etching back of the second dielectric layer, a sidewall of the second dielectric layer has a dishing, and the forming of the second epitaxial feature fully fills the dishing with no void trapped between the sidewall of the second dielectric layer and the second epitaxial feature. In some embodiments, the method further includes prior to the depositing of the first dielectric layer, depositing a dielectric liner in the inner spacer recesses. The dielectric liner and the first dielectric layer include different material compositions. In some embodiments, the replacing of the dummy gate stack breaks through the dielectric liner, such that the metal gate structure is in contact with the first dielectric layer.

In yet another exemplary aspect, the present disclosure is directed to a semiconductor structure. The semiconductor structure includes a base fin over a substrate, a first source/drain feature and a second source/drain feature over the base fin, nanostructures extending between the first source/drain feature and the second source/drain feature, a gate structure wrapping around each of the nanostructures, and a plurality of inner spacers interleaving the nanostructures. Each of the inner spacers includes a liner and a bulk dielectric portion surrounded by the liner, and the bulk dielectric portion includes a first sub-layer and a second sub-layer. In some embodiments, the bulk dielectric portion further includes a seam inside the first sub-layer and capped by the second sub-layer. In some embodiments, an interface between the first sub-layer and the second sub-layer has a V shape. In some embodiments, a sidewall of the bulk dielectric portion has a dishing profile, and one of the first and second source/drain features traps a void between the sidewall of the bulk dielectric portion and the one of the first and second source/drain features.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes channel layers interleaved by sacrificial layers;
patterning the stack to form a fin-shaped structure;
forming a dummy gate stack over a channel region of the fin-shaped structure;
depositing a gate spacer layer over the dummy gate stack;
after the depositing of the gate spacer layer, recessing a source/drain region of the fin-shaped structure;
selectively removing the sacrificial layers in the channel region to release the channel layers as channel members;
depositing a dummy layer in space between the channel members;
selectively and partially recessing the dummy layer to form inner spacer recesses;
depositing a first dielectric layer in the inner spacer recesses;
etching back the first dielectric layer;
after the etching back of the first dielectric layer, depositing a second dielectric layer over the first dielectric layer;
etching back the second dielectric layer to form inner spacers in the inner spacer recesses, the inner spacers including at least the first dielectric layer and the second dielectric layer;
forming a source/drain feature over the source/drain region;
removing the dummy gate stack;
removing the dummy layer; and
forming a gate structure to wrap around each of the channel members.

2. The method of claim 1, wherein the depositing of the first dielectric layer traps a seam inside the first dielectric layer.

3. The method of claim 2, wherein the etching back of the first dielectric layer opens the seam.

4. The method of claim 3, wherein the depositing of the second dielectric layer seals the seam.

5. The method of claim 1, wherein the depositing of the first dielectric layer formed a beaked opening, and the etching back of the first dielectric layer expands an aperture of the beaked opening.

6. The method of claim 5, wherein the depositing of the second dielectric layer fully fills the expanded beaked opening with the second dielectric layer with no seam trapped therein.

7. The method of claim 1, wherein after the etching back of the second dielectric layer, a sidewall of the second dielectric layer has a dishing, and wherein the forming of the source/drain feature traps a void between the sidewall of the second dielectric layer and the source/drain feature.

8. The method of claim 1, wherein after the etching back of the second dielectric layer, a sidewall of the second dielectric layer has a dishing, and wherein the forming of the source/drain feature fully fills the dishing with no void trapped between the sidewall of the second dielectric layer and the source/drain feature.

9. The method of claim 1, further comprising:
prior to the depositing of the first dielectric layer, depositing a dielectric liner in the inner spacer recesses,
wherein the first dielectric layer is deposited on the dielectric liner, and wherein the inner spacers include the dielectric liner, the first dielectric layer, and the second dielectric layer.

10. The method of claim 1, wherein the forming of the source/drain feature includes:
prior to the depositing of the second dielectric layer, forming a bottom portion of the source/drain feature; and
after the etching back of the second dielectric layer, forming a top portion of the source/drain feature.

11. A method, comprising:
forming a fin-shaped structure protruding from a substrate;
forming a dummy gate stack across the fin-shaped structure;
depositing a gate spacer layer over the dummy gate stack;
after the depositing of the gate spacer layer, recessing a region of the fin-shaped structure to form a trench;
forming inner spacer recesses on sidewalls of fin-shaped structure facing the trench;
depositing a first dielectric layer in the inner spacer recesses;
etching back the first dielectric layer;
forming a first epitaxial feature in a bottom portion of the trench;
after the forming of the first epitaxial feature, depositing a second dielectric layer on the first dielectric layer;
etching back the second dielectric layer to form inner spacers in the inner spacer recesses;
after the etching back of the second dielectric layer, forming a second epitaxial feature in a top portion of the trench; and
replacing the dummy gate stack with a metal gate structure, the inner spacers interposing the metal gate structure and the second epitaxial feature.

12. The method of claim 11, wherein the depositing of the first dielectric layer traps a seam inside the first dielectric layer, and wherein the etching back of the first dielectric layer opens the seam.

13. The method of claim 12, wherein the depositing of the second dielectric layer traps a void between the first dielectric layer and the second dielectric layer.

14. The method of claim 13, wherein the void is connected to the seam.

15. The method of claim 11, wherein after the etching back of the second dielectric layer, a sidewall of the second dielectric layer has a dishing, and wherein the forming of the second epitaxial feature fully fills the dishing with no void trapped between the sidewall of the second dielectric layer and the second epitaxial feature.

16. The method of claim 11, further comprising:
prior to the depositing of the first dielectric layer, depositing a dielectric liner in the inner spacer recesses, wherein the dielectric liner and the first dielectric layer include different material compositions.

17. The method of claim 16, wherein the replacing of the dummy gate stack breaks through the dielectric liner, such that the metal gate structure is in contact with the first dielectric layer.

18. A semiconductor structure, comprising:
a base fin over a substrate;
a first source/drain feature and a second source/drain feature over the base fin;
a plurality of nanostructures extending between the first source/drain feature and the second source/drain feature;
a gate structure wrapping around each of the nanostructures; and
a plurality of inner spacers interleaving the nanostructures,
wherein each of the inner spacers includes a liner and a bulk dielectric portion surrounded by the liner, and wherein the bulk dielectric portion includes a first sub-layer and a second sub-layer.

19. The semiconductor structure of claim 18, wherein the bulk dielectric portion further includes a seam inside the first sub-layer and capped by the second sub-layer.

20. The semiconductor structure of claim 18, wherein a sidewall of the bulk dielectric portion has a dishing profile, and one of the first and second source/drain features traps a void between the sidewall of the bulk dielectric portion and the one of the first and second source/drain features.
